(19) United States
(12) Patent Application Publication
(10) Pub. No.: US 2026/0358406 A1
(43) Pub. Date: Nov. 12, 2026

(54) SEMICONDUCTOR DEVICE SUPPORTING TEST OPERATION IN A TEST SYSTEM AND OPERATING METHOD OF THE SAME

(71) Applicant: SK hynix Inc., Icheon-si (KR)

(72) Inventor: Do Hoon KIM, Icheon-si (KR)

(21) Appl. No.: 19/400,353

(22) Filed: Nov. 25, 2025

(30) Foreign Application Priority Data
May 8, 2025 (KR) 10-2025-0059721

(51) Int. Cl. G01R 31/28

(52) U.S. Cl. CPC G01R 31/2868; G01R 31/2874

(57) ABSTRACT

A method of testing a semiconductor device includes selectively connecting an input stage of a source-follower circuit to a target circuit connected to a ground or source-voltage stage that performs a preset operation in an enable state, selectively connecting an output stage of the source-follower circuit to a measurement pad, measuring a first ground level or a first power-supply level through the measurement pad when the target circuit is disabled, measuring a second ground level or a second power-supply level through the measurement pad when the target circuit is enabled, and calculating a difference between the first and second ground levels as a ground-variation level or between the first and second power-supply levels as a power-supply-variation level, the semiconductor device including the target circuit, the source-follower circuit, and the measurement pad.

### CROSS-REFERENCE TO RELATED APPLICATION

This application claims priority under 35 U.S.C. § 119(a) to Korean Patent Application No. 10-2025-0059721, filed in the Korean Intellectual Property Office on May 8, 2025, the entire contents of which are incorporated herein by reference.

### BACKGROUND

### 1. Field

Exemplary embodiments relate to a semiconductor design technology, and particularly, to a semiconductor device supporting a test operation, an operating method of the same, and a test system including the same.

### 2. Discussion of the Related Art

Various tests, such as various tests at a wafer level and a package level, must be performed on a semiconductor device during a manufacturing process. In one of the various tests, differences in levels are checked between the levels of a source voltage and a ground voltage that are supplied to a specific circuit in the disable state of the specific circuit (such as a phase-locked loop (PLL) circuit included in the semiconductor device) and the levels of the source voltage and the ground voltage that are supplied to the specific circuit in the enable state of the specific circuit.

In the case of a specific circuit, such the PLL circuit, the results of the test operation are very important because a frequency offset may be different depending on the level of the source voltage and ground voltage supplied to the specific circuit.

Conventionally, the test operation includes an operation of measuring the levels of the source voltage and the ground voltage through a measurement pad when the specific circuit and the measurement pad have been isolated. To this end, conventionally, a method of isolating the specific circuit and the measurement pad by disposing a unit gain buffer between the specific circuit and the measurement pad is used. However, in view of the characteristics of the unit gain buffer, there is a problem in that the accuracy of the test operation decreases as the power supply node approaches the power supply voltage level and as the ground node approaches the ground voltage level.

### SUMMARY

Various embodiments are directed to providing a semiconductor device capable of performing a test operation by isolating a specific circuit and a measurement pad using a source-follower circuit in order to measure a variation in the levels of a source voltage and a ground voltage that are supplied to the specific circuit, and an operating method of the semiconductor device, and a test system including the semiconductor device.

Technical objects to be achieved by the present disclosure are not limited to the aforementioned object, and the other objects not described above may be evidently understood from the following description by a person having ordinary knowledge in the art to which the present disclosure pertains.

An aspect of an embodiment in the disclosure, a method of performing a test operation on a semiconductor device, the method may include:selectively connecting an input stage of a source-follower circuit to a target circuit, which is connected to a ground voltage stage or a source voltage stage to perform a preset operation in an enable state; selectively connecting an output stage of the source-follower circuit to a measurement pad; measuring, as a first level measurement operation, a first ground level or a first power supply level through the measurement pad in a state in which the target circuit is disabled; measuring, as a second level measurement operation, a second ground level or a second power supply level through the measurement pad in a state in which the target circuit is enabled; and calculating, as a first calculation operation, a difference between the first ground level and the second ground level as a ground variation level or a difference between the first power supply level and the second power supply level as a power supply variation level, wherein the semiconductor device may include the target circuit, the source-follower circuit and the measurement pad.

An aspect of an embodiment in the disclosure, a test system may include:a semiconductor device comprising a target circuit connected to a ground voltage stage or a source voltage stage and configured to perform a preset operation in an enable state, and a source-follower circuit having an input stage selectively connected to the ground voltage stage or the source voltage stage and an output stage selectively connected to a measurement pad; and a test device configured to perform a first level measurement operation of measuring a first ground level or a first power supply level through the measurement pad by connecting the ground voltage stage or the source voltage stage and the measurement pad to the input stage and output stage of the source-follower circuit, respectively, in a state in which the target circuit has been disabled, to perform a second level measurement operation of measuring a second ground level or a second power supply level through the measurement pad by connecting the ground voltage stage or the source voltage stage and the measurement pad to the input stage and output stage of the source-follower circuit, respectively, in a state in which the target circuit has been enabled, and to perform a first calculation operation of calculating a difference between the first ground level and the second ground level as a ground variation level or calculating a difference between the first power supply level and the second power supply level as a power supply variation level when performing a test operation on the semiconductor device.

The present technology can support a test operation having high accuracy even in the state in which a specific circuit, that is, the target of a test operation, and the measurement pad have been fully isolated by disposing the source-follower circuit between the specific circuit and the measurement pad within a semiconductor device.

Furthermore, it is possible to support a test operation having high accuracy regardless of temperature variation in the device because the test operation is performed by managing a variation in the level of a source voltage and a ground voltage according to the temperature variation in the form of a table.

### BRIEF DESCRIPTION OF THE DRAWINGS

FIG. 1 is a diagram for describing an example of a test system including a semiconductor device according to an embodiment of the present disclosure.

FIGS. 2A to 2C are diagrams for describing an example of a test operation of disposing a PMOS source-follower circuit in a semiconductor device according to an embodiment of the present disclosure and measuring a variation in the level of a ground voltage.

FIGS. 3A to 3D are diagrams for describing an example of a test operation of disposing a PMOS source-follower circuit in a semiconductor device and measuring a variation in the level of the ground voltage according to a temperature variation according to an embodiment of the present disclosure.

FIGS. 4A to 4C are diagrams illustrating an example of a test operation using an NMOS source-follower circuit in a semiconductor device and measuring a variation in the level of a source voltage according to an embodiment of the present disclosure.

FIGS. 5A to 5D are diagrams illustrating an example of a test operation of disposing an NMOS source-follower circuit in a semiconductor device and measuring a variation in the level of a source voltage corresponding to temperature variation according to an embodiment of the present disclosure.

### DETAILED DESCRIPTION

Various embodiments of the present disclosure are described below with reference to the accompanying drawings. Elements and features of the disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language includes hardware, such as for example circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that implement or perform one or more tasks.

As used in the disclosure, the term ‘circuitry’ or ‘logic’ refers to all of the following:(a) hardware-only circuit implementations (such as implementations in only analog and/or digital circuitry) and (b) combinations of circuits and software (and/or firmware), such as (as applicable):(i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or a portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that the terms precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. For example, the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

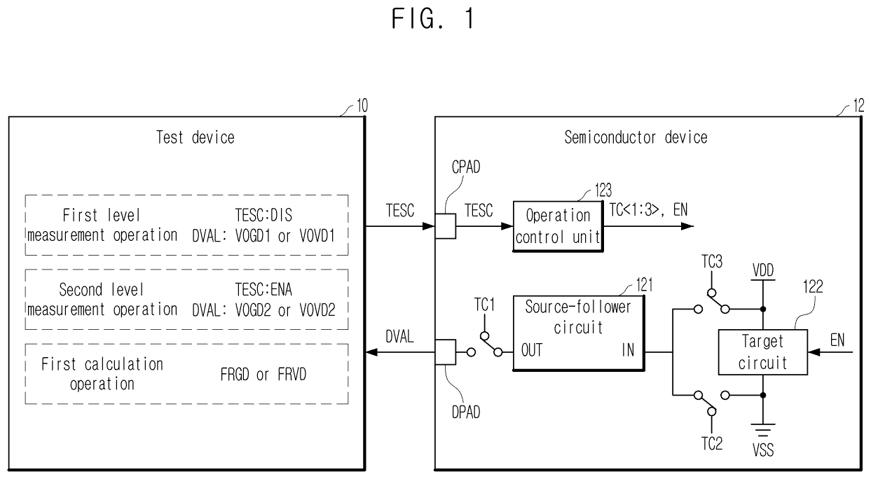

FIG. 1 is a diagram for describing an example of a test system including a semiconductor device according to an embodiment of the present disclosure.

Referring to FIG. 1, a test system may include a test device 10 and a semiconductor device 12.

Semiconductor device 12 may include a target circuit 122, a source-follower circuit 121, and an operation control unit 123.

Specifically, the target circuit 122 is connected to a ground voltage (VSS) stage or a source voltage (VDD) stage, and may perform a preset operation in the enable state.

According to an embodiment, the target circuit 122 may refer to at least one circuit, from any among a plurality of circuits (not illustrated) included in the semiconductor device 12. For example, assuming that the semiconductor device 12 is a semiconductor memory device, a plurality of circuits, such as a phase-locked loop (PLL) circuit, a delay-locked loop (DLL) circuit, a voltage generation circuit, and a data input/output circuit, may be included in the semiconductor memory device. At least one circuit, from among any of the plurality of circuits, may be selected as the target circuit 122. Furthermore, a “preset operation” that is performed when the target circuit 122 is in the enable state may be different depending on which circuit of the plurality of circuits included in the semiconductor device 12 is selected as the target circuit 122.

Furthermore, the source-follower circuit 121 may have an input stage IN selectively connected to the ground voltage (VSS) stage or the source voltage (VDD) stage, connected to the target circuit 122, and may have an output stage OUT selectively connected to a measurement pad DPAD.

In this case, the source-follower circuit 121 may refer to a circuit that transfers a signal that is applied to the input stage IN to the output stage OUT without almost any change while electrically isolating the input stage IN and the output stage OUT. That is, the source-follower circuit 121 can operate in a state in which the input stage IN and the output stage OUT rarely affect each other because impedance of the input stage IN of the source-follower circuit 121 is high and impedance of the output stage OUT of the source-follower circuit 121 is low. As described here, a transfer “without almost any change” means that the level of a signal that is applied to the input stage IN and the level of a signal that is output from the output stage OUT may have a difference corresponding to the threshold voltage level of a CMOS transistor because a CMOS transistor is included in the source-follower circuit 121.

Furthermore, the operation control unit 123 may control operations of the target circuit 122 and the source-follower circuit 121 in response to a test control signal TESC that is input from the outside of the semiconductor device 12. That is, the operation control unit 123 may control operations of the target circuit 122 and the source-follower circuit 121 in response to the test control signal TESC that is applied from the test device 10.

For example, the operation control unit 123 may enable or disable an operation of the target circuit 122 in response to the test control signal TESC. Furthermore, in response to the test control signal TESC, the operation control unit 123 may connect the source voltage (VDD) stage that is connected to the target circuit 122 to the input stage IN of the source-follower circuit 121, and may disconnect the ground voltage (VSS) stage that is connected to the target circuit 122 to the input stage IN of the source-follower circuit 121. Alternatively, in response to the test control signal TESC, the operation control unit 123 might not connect the source voltage (VDD) stage that is connected to the target circuit 122 to the input stage IN of the source-follower circuit 121, and may connect the ground voltage (VSS) stage that is connected to the target circuit 122 to the input stage IN of the source-follower circuit 121. Furthermore, the operation control unit 123 might or might not connect the output stage OUT of the source-follower circuit 121 to the measurement pad DPAD in response to the test control signal TESC.

A test system including the test device 10 and the semiconductor device 12 may perform a test operation on the semiconductor device 12 as follows through the test device 10.

First, when performing a test operation on the semiconductor device 12, in order to perform a first level measurement operation, the test device 10 may connect the ground voltage (VSS) stage or the source voltage (VDD) stage that is connected to the target circuit 122 to the input stage IN of the source-follower circuit 121, and connect the measurement pad DPAD to the output stage OUT of the source-follower circuit 121 in the state in which the target circuit 122 has been disabled. To this end, the test device 10 may output the value of the test control signal TESC to the semiconductor device 12 by setting the value of the test control signal TESC as “DIS” (TESC:DIS). Furthermore, in response to the test control signal TESC set as the value “DIS”, the operation control unit 123 included in the semiconductor device 12 may disable the target circuit 122 by disabling an enable signal EN, may connect the measurement pad DPAD to the output stage OUT of the source-follower circuit 121 by enabling a first test signal TC1, and may connect the ground voltage (VSS) stage or the source voltage (VDD) stage that is connected to the target circuit 122 to the input stage IN of the source-follower circuit 121 by enabling a second test signal TC2 or a third test signal TC3. Accordingly, the level of the ground voltage (VSS) stage or the source voltage (VDD) stage that is connected to the target circuit 122 in the disable state may be output to the measurement pad DPAD without almost any change through the source-follower circuit 121. For example, the level of the ground voltage (VSS) stage or the source voltage (VDD) stage that is connected to the target circuit 122 in the disable state may be output to the measurement pad DPAD in the state in which the level of the ground voltage (VSS) stage or the source voltage (VDD) stage has a difference corresponding to only the threshold voltage level of the CMOS transistor included in the source-follower circuit 121 when applied to the input stage IN of the source-follower circuit 121.

At this time, the test device 10 may set the level of a signal that is output to the measurement pad DPAD of the semiconductor device 12 as a first ground level VOGD1 or a first power supply level VOVD1. That is, the test device 10 may set the level of the ground voltage (VSS) stage or the source voltage (VDD) stage that is connected to the target circuit 122 in the disable state, which is received from the semiconductor device 12 as the results of the first level measurement operation, as the first ground level VOGD1 or the first power supply level VOVD1.

Furthermore, when performing a test operation on the semiconductor device 12, in order to perform a second level measurement operation in which the target circuit 122 included in the semiconductor device 12 has been enabled, the test device 10 may connect the ground voltage (VSS) stage or the source voltage (VDD) stage that is connected to the target circuit 122 to the input stage IN of the source-follower circuit 121 and connect the measurement pad DPAD to the output stage OUT of the source-follower circuit 121. To this end, the test device 10 may set the value of the test control signal TESC as “ENA” (TESC:ENA). Furthermore, in response to the test control signal TESC set as the value “ENA”, the operation control unit 123 included in the semiconductor device 12 may enable the target circuit 122 by enabling the enable signal EN, may connect the measurement pad DPAD to the output stage OUT of the source-follower circuit 121 by enabling the first test signal TC1, and may connect the ground voltage (VSS) stage or the source voltage (VDD) stage that is connected to the target circuit 122 to the input stage IN of the source-follower circuit 121 by enabling the second test signal TC2 or the third test signal TC3. Accordingly, the level of the ground voltage (VSS) stage or the source voltage (VDD) stage that is connected to the target circuit 122 in the enable state may be output to the measurement pad DPAD without almost any change through the source-follower circuit 121. For example, the level of the ground voltage (VSS) stage or the source voltage (VDD) stage that is connected to the target circuit 122 in the enable state may be output through the measurement pad DPAD in the state in which the level of the ground voltage (VSS) stage or the source voltage (VDD) stage has a difference corresponding to only the threshold voltage level of the CMOS transistor included in the source-follower circuit 121 when applied to the input stage IN of the source-follower circuit 121.

At this time, the test device 10 may set the level of a signal that is output to the measurement pad DPAD of the semiconductor device 12 as a second ground level VOGD2 or a second power supply level VOVD2. That is, the test device 10 may set the level of the ground voltage (VSS) stage or the source voltage (VDD) stage that is connected to the target circuit 122 in the enable state, which is received from the semiconductor device 12 as the result of the second level measurement operation, as the second ground level VOGD2 or the second power supply level VOVD2.

Furthermore, the test device 10 may perform a first calculation operation after completing the execution of the first level measurement operation and the second level measurement operation.

Specifically, the test device 10 may perform the first calculation operation of calculating a difference between the first ground level VOGD1 set during the first level measurement operation and the second ground level VOGD2 set during the second level measurement operation as a ground variation level FRGD.

Furthermore, the test device 10 may perform the first calculation operation of calculating a difference between the first power supply level VOVD1 set during the first level measurement operation and the second power supply level VOVD2 set during the second level measurement operation as a power supply variation level FRVD.

In other words, the test device 10 may receive the first ground level VOGD1 or the first power supply level VOVD1 when the target circuit 122 included in the semiconductor device 12 is in the disable state through the first level measurement operation. The first ground level VOGD1 or the first power supply level VOVD1 is a difference between the level of the ground voltage (VSS) stage or the source voltage (VDD) stage, whichever is input to the source-follower circuit 121, and the threshold voltage level of the CMOS transistor included in the source-follower circuit 121, and output through the measurement pad DPAD.

Furthermore, the test device 10 may receive the second ground level VOGD2 or the second power supply level VOVD2 when the target circuit 122 included in the semiconductor device 12 is in the enable state through the second level measurement operation. The second ground level VOGD2 or the second power supply level VOVD2 is a difference between the level of the ground voltage (VSS) or the source voltage (VDD), whichever is input to the source-follower circuit 121, and the threshold voltage level of the CMOS transistor included in the source-follower circuit 121 and output through the measurement pad DPAD.

Furthermore, the test device 10 may perform the first calculation operation of calculating a difference between the first ground level VOGD1 and the second ground level VOGD2, which is checked as the results of the execution of the first level measurement operation and the second level measurement operation, as the ground variation level FRGD.

Furthermore, the test device 10 may perform the first calculation operation of calculating a difference between the first power supply level VOVD1 and the second power supply level VOVD2, which is checked as the results of the execution of the first level measurement operation and the second level measurement operation, as the power supply variation level FRVD.

After measuring the ground variation level FRGD or the power supply variation level FRVD by performing the test operation on the semiconductor device 12, the test device 10 may perform a normal operation on the semiconductor device 12.

That is, the semiconductor device 12 may adjust execution conditions for a preset internal operation to be performed within the semiconductor device with reference to the ground variation level FRGD or the power supply variation level FRVD after the start of the normal operation.

For example, when it is assumed that the semiconductor device 12 is a semiconductor memory device and the target circuit 122 is a PLL circuit, the semiconductor device 12 may adjust the frequency offset of a clock generated by the PLL circuit with reference to the ground variation level FRGD or the power supply variation level FRVD.

According to an embodiment, a test device 10 illustrated in FIG. 1 may be a device that only controls a semiconductor device 12 during a test operation. That is, in a normal operation, a semiconductor controller (not illustrated) that is physically separated from the test device 10 illustrated in FIG. 1 may be connected to the semiconductor device 12, and the test device 10 might not be connected to the semiconductor device 12.

According to another embodiment, although not directly illustrated in FIG. 1, the semiconductor controller (not illustrated) that controls a test operation and a normal operation for the semiconductor device 12 may be connected to the semiconductor device 12. That is, the semiconductor controller that is connected to the semiconductor device 12 may include the test device 10 in a module that controls a test operation for the semiconductor device 12, and a normal control device (not illustrated) in a module that controls a normal operation for the semiconductor device 12. In such a case, the test device 10 and the normal control device can be enabled or disabled in the operations of a semiconductor controller that is connected to the semiconductor device 12.

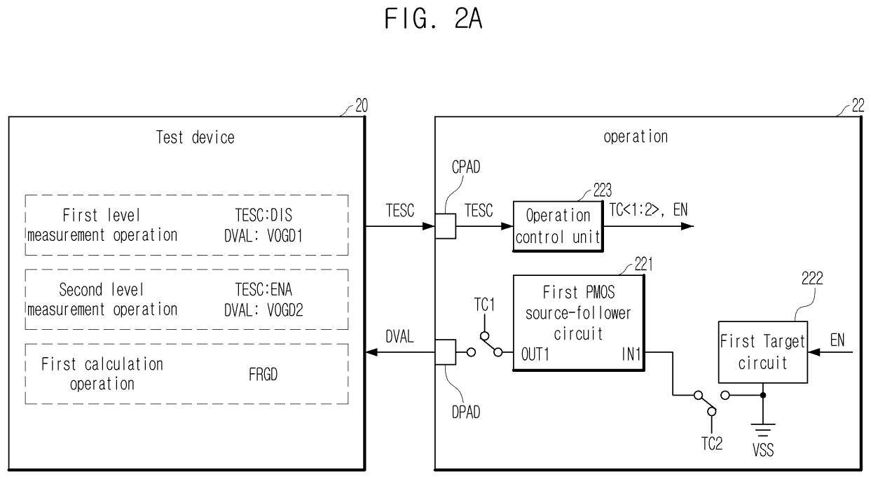

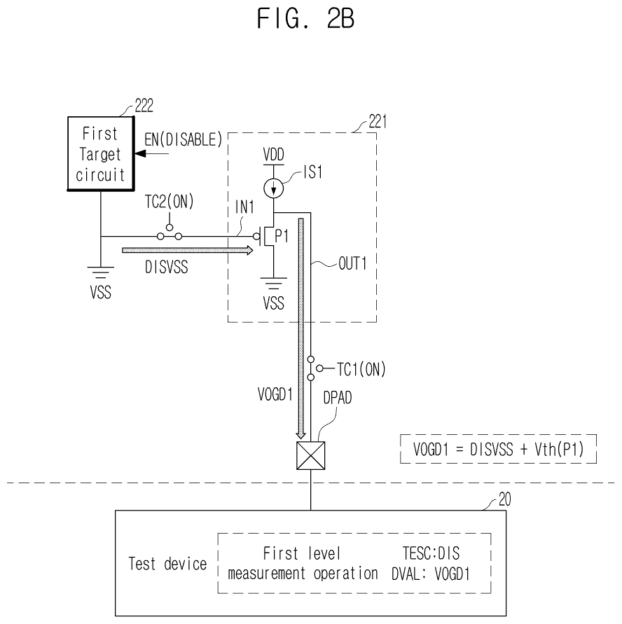

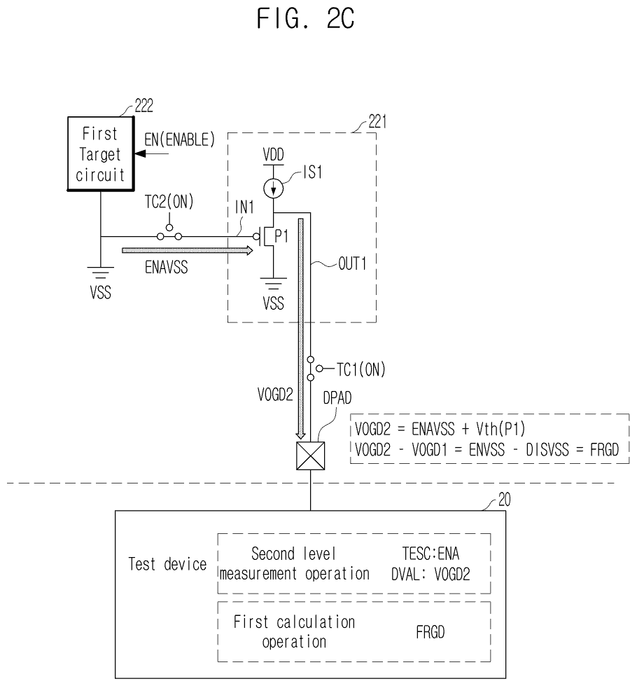

FIGS. 2A to 2C are diagrams for describing an example of a test operation of disposing a PMOS source-follower circuit in a semiconductor device according to an embodiment of the present disclosure and measuring a variation in the level of a ground voltage.

In FIGS. 2A to 2C, the source-follower circuit 121 disclosed in FIG. 1 is a PMOS source-follower circuit that measures the level of the ground voltage (VSS) stage. That is, FIGS. 2A to 2C are diagrams illustrating the application of a PMOS source-follower circuit as the source-follower circuit 121 disclosed in FIG. 1 to accurately transfer the level of the ground voltage (VSS) stage.

First, referring to FIG. 2A, a semiconductor device 22 may include a first target circuit 222, a first PMOS source-follower circuit 221, and an operation control unit 223.

The first target circuit 222 is connected to a ground voltage (VSS) stage, and may perform a preset operation in the enable state.

The first PMOS source-follower circuit 221 may have a first input stage IN1 selectively connected to the ground voltage (VSS) stage, which is connected to the first target circuit 222, and may have a first output stage OUT1 selectively connected to a measurement pad DPAD.

The operation control unit 223 may control operations of the first target circuit 222 and the first PMOS source-follower circuit 221 in response to a test control signal TESC that is input to the semiconductor device 22. That is, the operation control unit 223 may control operations of the first target circuit 222 and the first PMOS source-follower circuit 221 in response to the test control signal TESC that is applied to semiconductor device 22 from a test device 20.

For example, the operation control unit 223 may enable or disable an operation of the first target circuit 222 in response to the test control signal TESC. Furthermore, the operation control unit 223 may connect or disconnect the ground voltage (VSS) stage that is connected through the first target circuit 222 to the first input stage IN1 of the first PMOS source-follower circuit 221 in response to the test control signal TESC. Furthermore, the operation control unit 223 may connect or disconnect the first output stage OUT1 of the first PMOS source-follower circuit 221 to the measurement pad DPAD in response to the test control signal TESC.

The first target circuit 222 illustrated in FIG. 2A may be the same circuit as the target circuit 122 illustrated in FIG. 1 or may be a circuit different from the target circuit 122 illustrated in FIG. 1. That is, the first target circuit 222 illustrated in FIG. 2A refers to a circuit that is selected as a target for an operation of transferring the level of the ground voltage (VSS) stage connected to the first target circuit 222 to the measurement pad DPAD without almost any change through the first PMOS source-follower circuit 221, and might not be limited to a specific circuit. Accordingly, although not illustrated, a source voltage (VDD) stage may be connected to the first target circuit 222, but may be in the state in which the level of the source voltage (VDD) stage has not been illustrated as a target to be measured.

A test system including the test device 20 and the semiconductor device 22 may perform a test operation on the semiconductor device 22 as follows through the test device 20.

Referring to both FIGS. 2A and 2B, when performing a test operation on the semiconductor device 22, in order to perform a first level measurement operation, the test device 20 may connect the ground voltage (VSS) stage that is connected to the first target circuit 222 to the first input stage IN1 of the first PMOS source-follower circuit 221 and connect the measurement pad DPAD to the first output stage OUT1 of the first PMOS source-follower circuit 221 in the state in which the first target circuit 222 included in the semiconductor device 22 has been disabled. To this end, the test device 20 may output the value of the test control signal TESC to the semiconductor device 22 by setting the value of the test control signal TESC as “DIS” (TESC:DIS). Furthermore, in response to the test control signal TESC set as the value “DIS”, the operation control unit 223 included in the semiconductor device 22 may disable the first target circuit 222 by disabling (DISABLE) an enable signal EN, may connect the measurement pad DPAD to the first output stage OUT1 of the first PMOS source-follower circuit 221 by enabling (ON) a first test signal TC1, and may connect the ground voltage (VSS) stage that is connected to the first target circuit 222 to the first input stage IN1 of the first PMOS source-follower circuit 221 by enabling (ON) a second test signal TC2. Accordingly, the level of the ground voltage (VSS) stage that is connected to the first target circuit 222 in the disable state may be output to the measurement pad DPAD without almost any change through the first PMOS source-follower circuit 221. A transfer “without almost any change” means that the level of a signal that is applied to the input stage IN1 and the level of a signal that is output from the output stage OUT1 may have a difference corresponding to the threshold voltage level of a PMOS transistor because a PMOS transistor is included in the source-follower circuit 221.

Referring to FIG. 2B, the first PMOS source-follower circuit 221 may include a PMOS transistor P1 having a gate connected to the first input stage IN1, a drain connected to the ground voltage (VSS) stage, and a source connected to the first output stage OUT1, and a current source IS1 that is connected between the source voltage (VDD) stage and the source of the PMOS transistor P1. For reference, the current source IS1 is a circuit that stably operates the PMOS transistor P1 in an active area by controlling the PMOS transistor P1 so that a drain current having a preset size flows in the direction of the drain of the PMOS transistor P1 from the source of the PMOS transistor P1. A detailed construction of the current source IS1 is an already known technology, and will not be described hereinafter in detail.

In this case, the first PMOS source-follower circuit 221 may transfer, to the first output stage OUT1, a level (DISVSS+Vth(P1)) in which the threshold voltage level (Vth(P1)) of the PMOS transistor P1 is added to the level DISVSS of the ground voltage (VSS) stage that is applied to the first input stage IN1 and that is connected to the first target circuit 222 in the disable state.

Accordingly, a first ground level VOGD1 that is received by the test device 20 from the semiconductor device 22 as the result of the first level measurement operation may be the level (DISVSS+Vth(P1)) in which the threshold voltage level (Vth(P1)) of the PMOS transistor P1 included in the first PMOS source-follower circuit 221 is added to the level DISVSS of the ground voltage (VSS) stage that is connected to the first target circuit 222 in the disable state.

Furthermore, referring to both FIGS. 2A and 2C, when performing a test operation on the semiconductor device 22, in order to perform a second level measurement operation, the test device 20 may connect the ground voltage (VSS) stage that is connected to the first target circuit 222 to the first input stage IN1 of the first PMOS source-follower circuit 221 and connect the measurement pad DPAD to the first output stage OUT1 of the first PMOS source-follower circuit 221 in the state in which the first target circuit 222 included in the semiconductor device 22 has been enabled. To this end, the test device 20 may output the value of the test control signal TESC to the semiconductor device 22 by setting the value of the test control signal TESC as “ENA” (TESC:ENA). Furthermore, in response to the test control signal TESC set as the value “ENA”, the operation control unit 223 included in the semiconductor device 22 may enable the first target circuit 222 by enabling (ENABLE) the enable signal EN, may connect the measurement pad DPAD to the first output stage OUT1 of the first PMOS source-follower circuit 221 by enabling (ON) the first test signal TC1, and may connect the ground voltage (VSS) stage that is connected to the first target circuit 222 to the first input stage IN1 of the first PMOS source-follower circuit 221 by enabling (ON) the second test signal TC2. Accordingly, the level of the ground voltage (VSS) stage that is connected to the first target circuit 222 in the enable state may be output to the measurement pad DPAD without almost any change through the first PMOS source-follower circuit 221.

More specifically, the first PMOS source-follower circuit 221 may include the PMOS transistor P1 having the gate connected to the first input stage IN1, the drain connected to the ground voltage (VSS), and the source connected to the first output stage OUT1, and the current source IS1 that is connected between the source voltage (VDD) stage and the source of the PMOS transistor P1.

Referring to FIG. 2C, the first PMOS source-follower circuit 221 may transfer, to the first output stage OUT1, a level (ENAVSS+Vth(P1)) in which the threshold voltage level (Vth(P1)) of the PMOS transistor P1 is added to the level ENAVSS of the ground voltage (VSS) stage that is applied to the first input stage IN1 and that is connected to the first target circuit 222 in the enable state.

Accordingly, a second ground level VOGD2 that is received by the test device 20 from the semiconductor device 22 as the result of the second level measurement operation may be the level (ENAVSS+Vth(P1)) in which the threshold voltage level (Vth(P1)) of the PMOS transistor P1 included in the first PMOS source-follower circuit 221 is added to the level ENAVSS of the ground voltage (VSS) stage that is connected to the first target circuit 222 in the enable state.

Furthermore, the test device 20 may perform a first calculation operation after completing the execution of the first level measurement operation and the second level measurement operation. Specifically, the test device 20 may perform the first calculation operation of calculating a difference between the first ground level VOGD1 set during the first level measurement operation and the second ground level VOGD2 set during the second level measurement operation as a ground variation level FRGD.

The first ground level VOGD1 set during the first level measurement operation may be the level (DISVSS+Vth(P1)) in which the threshold voltage level (Vth(P1)) of the PMOS transistor P1 included in the first PMOS source-follower circuit 221 is added to the level DISVSS of the ground voltage (VSS) stage that is connected to the first target circuit 222 in the disable state. Furthermore, the second ground level VOGD2 set during the second level measurement operation may be the level (ENAVSS+Vth(P1)) in which the threshold voltage level (Vth(P1)) of the PMOS transistor P1 included in the first PMOS source-follower circuit 221 is added to the level ENAVSS of the ground voltage (VSS) stage that is connected to the first target circuit 222 in the enable state.

Accordingly, the ground variation level FRGD indicative of the difference between the first ground level VOGD1 set during the first level measurement operation and the second ground level VOGD2 set during the second level measurement operation (ENVSS-DISVSS or DISVSS-ENVSS) may be indicative of a difference between the level ENAVSS of the ground voltage (VSS) stage that is connected to the first target circuit 222 in the enable state and the level DISVSS of the ground voltage (VSS) stage that is connected to the first target circuit 222 in the disable state. For example, the ground variation level FRGD may be a level (ENVSS-DISVSS) in which the level DISVSS of the ground voltage (VSS) stage that is connected to the first target circuit 222 in the disable state is subtracted from the level ENAVSS of the ground voltage (VSS) stage that is connected to the first target circuit 222 in the enable state because it is expected that the second ground level VOGD2 set during the second level measurement operation has a higher level than the first ground level VOGD1 set during the first level measurement operation.

In other words, the test device 20 may measure the level of the ground voltage (VSS) stage as the first ground level VOGD1 by receiving the level of the ground voltage (VSS) stage without almost any change through the measurement pad DPAD when the first target circuit 222 included in the semiconductor device 22 is in the disable state through the first level measurement operation.

Furthermore, the test device 20 may measure the level of the ground voltage (VSS) stage as the second ground level VOGD2 by receiving the level of the ground voltage (VSS) stage without almost any change through the measurement pad DPAD when the first target circuit 222 included in the semiconductor device 22 is in the enable state through the second level measurement operation.

The test device 20 may perform the first calculation operation of calculating a ground variation level FRGD, which is the difference between the first ground level VOGD1 and the second ground level VOGD2 checked as the results of the execution of the first level measurement operation and the second level measurement operation.

After measuring the ground variation level FRGD by performing the test operation on the semiconductor device 22, the test device 20 may perform a normal operation on the semiconductor device 22. That is, the semiconductor device 22 may adjust execution conditions for a preset internal operation to be performed within the semiconductor device with reference to the ground variation level FRGD after the start of the normal operation. For example, when it is assumed that the semiconductor device 22 is a semiconductor memory device and the first target circuit 222 is a PLL circuit, the semiconductor device 22 may adjust the frequency offset of a clock generated by the PLL circuit with reference to the ground variation level FRGD.

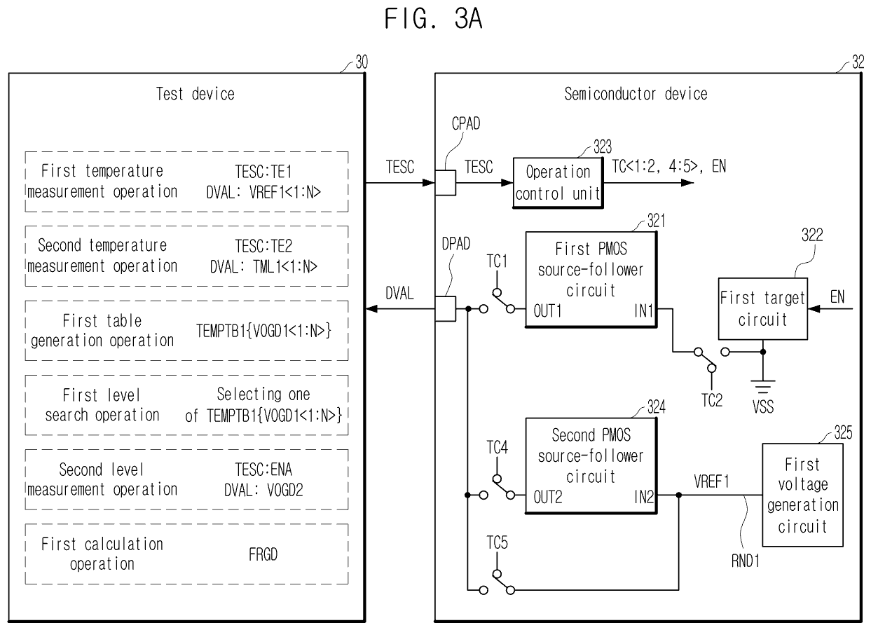

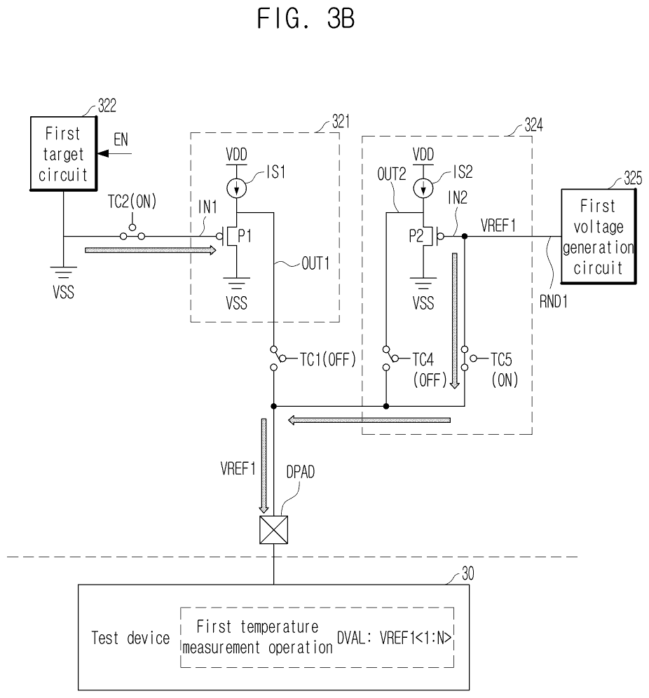

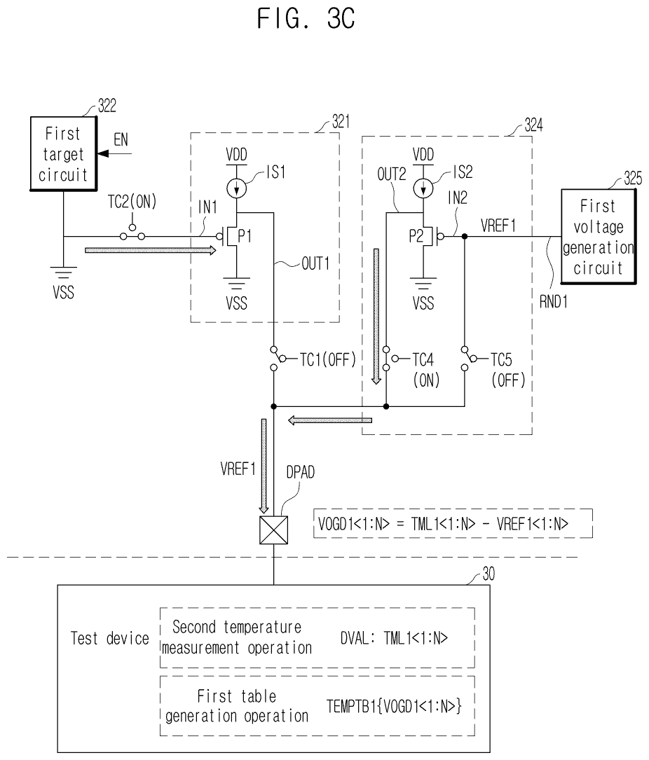

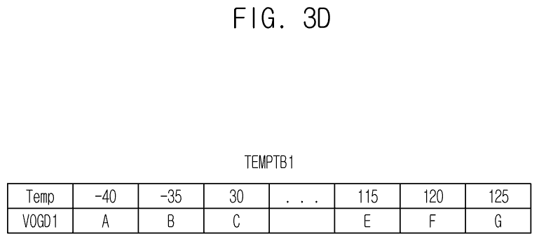

FIGS. 3A to 3D are diagrams for describing an example of a test operation of disposing a PMOS source-follower circuit in a semiconductor device and measuring a variation in the level of a ground voltage according to a temperature variation according to an embodiment of the present disclosure.

A test operation capable of measuring the level of the ground voltage (VSS) stage at a current time without incorporating semiconductor device temperature variations as a variable (a temperature non-incorporation mode) has been described above with reference to FIGS. 2A to 2C. Hereinafter, a test operation capable of measuring the level of the ground voltage (VSS) stage according to temperature variations of a semiconductor device 32 (a temperature incorporation mode) by using the temperature variation as a variable will be described with reference to FIGS. 3A to 3D.

First, referring to FIG. 3A, the semiconductor device 32 may include a first target circuit 322, a first PMOS source-follower circuit 321, a second PMOS source-follower circuit 324, a first voltage generation circuit 325, and an operation control unit 323.

The first target circuit 322 is connected to a ground voltage (VSS) stage, and may perform a preset operation in the enable state.

The first PMOS source-follower circuit 321 may have a first input stage IN1 selectively connected to the ground voltage (VSS) stage that is connected to the first target circuit 322, and may have a first output stage OUT1 selectively connected to a measurement pad DPAD.

The first voltage generation circuit 325 may generate a first reference voltage VREF1 and supply the first reference voltage VREF1 to a first reference voltage stage RND1. For example, the first voltage generation circuit 325 may include a bandgap reference circuit, and may be a circuit that operates so that the level of the first reference voltage VREF1 can maintain a preset level regardless of temperature variation in a device. However, the level of the first reference voltage VREF1 may be slightly changed from the preset level because the bandgap reference circuit included in the first voltage generation circuit 325 is a circuit component that includes a diode and a CMOS transistor. That is, maintaining the level of the first reference voltage VREF1 at a preset level regardless of temperature variation means that although temperature variation occurs, the level of the first reference voltage VREF1 maintains a level that does not greatly vary from a preset level, and does not mean that when a temperature variation occurs, the level of the first reference voltage VREF1 never changes. A detailed construction of the bandgap reference circuit is already known technology, and thus will not be described hereinafter in detail.

A second input stage IN2 of the second PMOS source-follower circuit 324, which is connected to the first reference voltage stage RND1, may be selectively connected to the measurement pad DPAD. A second output stage OUT2 of the second PMOS source-follower circuit 324 may be selectively connected to the measurement pad DPAD.

The operation control unit 323 may control operations of the first target circuit 322, the first PMOS source-follower circuit 321, and the second PMOS source-follower circuit 324 in response to a test control signal TESC that is input from the outside of the semiconductor device 32. That is, the operation control unit 323 may control operations of the first target circuit 322, the first PMOS source-follower circuit 321, and the second PMOS source-follower circuit 324 in response to the test control signal TESC that is applied to the semiconductor device 32 from a test device 30.

For example, the operation control unit 323 may enable or disable an operation of the first target circuit 322 in response to the test control signal TESC. The operation control unit 323 may connect or disconnect the ground voltage (VSS) stage that is connected through the first target circuit 322 to the first input stage IN1 of the first PMOS source-follower circuit 321 in response to the test control signal TESC. The operation control unit 323 may connect or disconnect the first output stage OUT1 of the first PMOS source-follower circuit 321 to the measurement pad DPAD in response to the test control signal TESC. The operation control unit 323 may connect or disconnect the second input stage IN2 of the second PMOS source-follower circuit 324 to which the first reference voltage stage RND1 is connected to the measurement pad DPAD in response to the test control signal TESC. The operation control unit 323 may connect or disconnect the second output stage OUT2 of the second PMOS source-follower circuit 324 to the measurement pad DPAD in response to the test control signal TESC.

A test system including the test device 30 and the semiconductor device 32 may repeatedly perform a temperature measurement operation according to the temperature variation of the semiconductor device 32, and may generate a first temperature table TEMPTB1 including a first ground level VOGD1 by creating a table with measurement results. The temperature measurement operations can be performed before a test operation on the semiconductor device 32 using the test device 30. That is, the test system may generate a first temperature table TEMPTB1 including the first ground level VOGD1 according to the device temperature variation by repeatedly performing the temperature measurement operation using the test device 30 while intentionally changing a temperature of the semiconductor device 32, with results in the form of a table as schematically illustrated in FIG. 3D.

The test system may intentionally change the temperature of the semiconductor device 32. For example, as illustrated in FIG. 3D, the test system may change a temperature of the semiconductor device 32 at intervals of 5 °C from −40 °C to 125 °C. Furthermore, the test system may repeat a first temperature measurement operation, a second temperature measurement operation, and a first table generation operation using the test device 30 whenever the test system changes the temperature of the semiconductor device 32. For example, after changing the temperature of the semiconductor device 32 to −40 °C, the test system may calculate “A”, that is, a value of the first ground level VOGD1 corresponding to the temperature of −40 °C, by performing a first temperature measurement operation, a second temperature measurement operation, and a first table generation operation through the test device 30. As another example, after changing the temperature of the semiconductor device 32 to 125 °C, the test system may calculate “G”, that is, a value of the first ground level VOGD1 corresponding to the temperature of 125 °C, by performing a first temperature measurement operation, a second temperature measurement operation, and a first table generation operation using the test device 30. Both “A” and “G” are included in the first temperature table TEMPTB1.

Referring to FIGS. 3A and 3B, in order to perform a first temperature measurement operation, the semiconductor device 32 may be configured with the ground voltage (VSS) stage, which is connected to the first target circuit 322, connected to the first input stage IN1 of the first PMOS source-follower circuit 321 and with the measurement pad DPAD not connected to the first output stage OUT1 of the first PMOS source-follower circuit 321. By setting the first target circuit 322, the first PMOS source-follower circuit 321 and the measurement pad DPAD in this way, the test device 30 sets a first measurement preparation state.

Furthermore, in order to perform the first temperature measurement operation, the test device 30 may transfer the first reference voltage VREF1 loaded onto the first reference voltage stage RND1 to the measurement pad DPAD, by connecting the second input stage IN2 of the second PMOS source-follower circuit 324, to which the first reference voltage stage RND1 is connected, to the measurement pad DPAD. In this case, the measurement pad DPAD is not connected to the second output stage OUT2 of the second PMOS source-follower circuit 324.

To this end, the test device 30 may set the value of the test control signal TESC as “TE1” (TESC:TE1) and output the value “TE1” to the semiconductor device 32.

Furthermore, the operation control unit 323 included in the semiconductor device 32 may disable (OFF) a first test signal TC1 so that the measurement pad DPAD is not connected to the first output stage OUT1 of the first PMOS source-follower circuit 321. In addition, in response to the test control signal TESC set as the value “TE1”, the operation control unit 323 enables (ON) a second test signal TC2 so that the ground voltage (VSS) stage that is connected to the first target circuit 322 is connected to the first input stage IN1 of the first PMOS source-follower circuit 321. Thus, these elements are placed in the first measurement preparation state with respect to each other.

Furthermore, in response to the test control signal TESC set as the value “TE1”, the operation control unit 323 included in the semiconductor device 32 might not connect the measurement pad DPAD to the second output stage OUT2 of the second PMOS source-follower circuit 324 by disabling (OFF) a fourth test signal TC4. Instead, the operation control unit 323 may connect the second input stage IN2 of the second PMOS source-follower circuit 324 to which the first reference voltage stage RND1 is connected to the measurement pad DPAD by enabling (ON) a fifth test signal TC5.

Accordingly, the test device 30 may receive the first reference voltage VREF1 through the measurement pad DPAD during the first temperature measurement operation.

More specifically, the second PMOS source-follower circuit 324 may include a PMOS transistor P2 having a gate connected to the second input stage IN2, which is connected to the first reference voltage (VREF1) stage, a drain connected to a ground voltage (VSS) stage, and a source connected to the second output stage OUT2, and a current source IS2 that is connected between a source voltage (VDD) stage and the source of the PMOS transistor P2. For reference, the current source IS2 is a circuit that stably operates the PMOS transistor P2 in an active area and controls the PMOS transistor P2 so that a drain current having a preset size flows in a direction from the source of the PMOS transistor P2 to the drain of the PMOS transistor P2. A detailed construction of the current source IS2 is an already known technology and thus will not be described hereinafter in detail.

When repeating the first temperature measurement operation for the semiconductor device 32 using the test device 30 after intentionally changing a temperature of the semiconductor device 32 for an N times as described above, the test system may measure N levels (VREF1<1:N>) of the first reference voltage VREF1 corresponding the N temperatures, respectively (where N is a natural number equal or greater than 2).

For example, when performing a first temperature measurement operation on the semiconductor device 32 using the test device 30 in the state in which a temperature of the semiconductor device 32 has changed to −30 °C, the test system may measure a level of the first reference voltage VREF1 corresponding to a temperature of −30 °C. As another example, when the test system performs the first temperature measurement operation on the semiconductor device 32 in the state in which a temperature of the semiconductor device 32 has changed into 115 °C, the test system may measure a level of the first reference voltage VREF1 corresponding to a temperature of 115 °C.

The test device 30 measures N levels (VREF1<1:N>) of the first reference voltage VREF1 corresponding to the N temperatures, respectively, by repeating the first temperature measurement operation as described above. During such measurements, the level of the first reference voltage VREF1 is slightly changed on the basis of a preset level depending on a temperature variation because the bandgap reference circuit included in the first voltage generation circuit 325 is a circuit component that operates with a diode and a CMOS transistor.

Furthermore, referring to FIGS. 3A and 3C, as in the first temperature measurement operation, in order to perform a second temperature measurement operation, the test device 30 may connect the ground voltage (VSS) stage, which is connected to the first target circuit 322, to the first input stage IN1 of the first PMOS source-follower circuit 321, and does not connect the measurement pad DPAD to the first output stage OUT1 of the first PMOS source-follower circuit 321. Thus, in the second temperature measurement operation, these elements are placed in the first measurement preparation state with respect to each other.

Furthermore, in order to perform the second temperature measurement operation, the test device 30 may connect the measurement pad DPAD and the second output stage OUT2 of the second PMOS source-follower circuit 324. The second input stage IN2 of the second PMOS source-follower circuit 324, to which the first reference voltage stage RND1 is connected, is disconnected from the measurement pad DPAD.

To this end, the test device 30 may set the value of the test control signal TESC as “TE2” (TESC:TE2) and output the value “TE2” as a signal to the semiconductor device 32.

Furthermore, the operation control unit 323 included in the semiconductor device 32 may disable (OFF) the first test signal TC1 so that the measurement pad DPAD is not connected to the first output stage OUT1 of the first PMOS source-follower circuit 321. Instead, in response to the test control signal TESC set as the value “TE2” the operation control unit 323 enables (ON) the second test signal TC2 so that the ground voltage (VSS) stage, which is connected to the first target circuit 322, is connected to the first input stage IN1 of the first PMOS source-follower circuit 321. Thus, these elements are placed in the first measurement preparation state with respect to each other.

Furthermore, in response to the test control signal TESC set as the value “TE2”, the operation control unit 323 included in the semiconductor device 32 may connect the measurement pad DPAD to the second output stage OUT2 of the second PMOS source-follower circuit 324 by enabling (ON) the fourth test signal TC4, and does not connect the second input stage IN2 of the second PMOS source-follower circuit 324, to which the first reference voltage stage RND1 is connected, to the measurement pad DPAD by disabling (OFF) the fifth test signal TC5.

Accordingly, a level (VREF1+Vth(P2)) may be output to the measurement pad DPAD. Here, the threshold voltage level (Vth(P2)) of the PMOS transistor P2 included in the second PMOS source-follower circuit 324 is added to the level of the first reference voltage VREF1 loaded onto the first reference voltage stage RND1. That is, during the second temperature measurement operation, the test device 30 may receive a first temperature operation level TML1, through the measurement pad DPAD, that is higher than the level of the first reference voltage VREF1 by the threshold voltage level (Vth(P2)) of the PMOS transistor.

More specifically, the second PMOS source-follower circuit 324 may include the PMOS transistor P2 having a gate connected to the second input stage IN2, which is connected to the first reference voltage (VREF1) stage, a drain connected to the ground voltage (VSS) stage, and a source connected to the second output stage OUT2, and the current source IS2 that is connected between the source voltage (VDD) stage and the source of the PMOS transistor P2.

When repeating the second temperature measurement operation for the semiconductor device 32 using the test device 30 after intentionally changing a temperature of the semiconductor device 32 for N times as described above, the test system may measure N levels (VML1<1:N>) of the first temperature operation level TML1 corresponding to the N temperatures, respectively, where N is a natural number equal or greater than 2.

For example, when performing the second temperature measurement operation on the semiconductor device 32 using the test device 30 when a temperature of the semiconductor device 32 has changed to −30 °C, the test system may measure a level of the first temperature operation level TML1 corresponding a temperature of −30 °C. As another example, when performing the second temperature measurement operation on the semiconductor device 32 using the test device 30 when a temperature of the semiconductor device 32 has changed into 115 °C, the test system may measure a level of the first temperature operation level TML1 corresponding to a temperature of 115 °C.

When the test device 30 performs first and second temperature measurement operations on the second PMOS source-follower circuit 324, the state of the first PMOS source-follower circuit 321 is in the first measurement preparation state. As a result, both the PMOS transistor P1 included in the first PMOS source-follower circuit 321 and the PMOS transistor P2 included in the second PMOS source-follower circuit 324 have the same state, that is, a turn-on state, during the interval in which the first and second temperature measurement operations are performed. Accordingly, while the test device 30 performs the first temperature measurement operation and the second temperature measurement operation on the semiconductor device 32, the threshold voltage level (Vth(P1)) of the PMOS transistor P1 included in the first PMOS source-follower circuit 321 and the threshold voltage level (Vth(P2)) of the PMOS transistor P2 included in the second PMOS source-follower circuit 324 may have the same level.

Furthermore, after completing the execution of the first temperature measurement operation and the second temperature measurement operation, the test device 30 may perform the first table generation operation. Specifically, the test device 30 may calculate a first ground level VOGD1, which is the difference (TML1−VREF1 or VREF1−TML1) between the level of the first reference voltage VREF1 set during the first temperature measurement operation and the first temperature operation level TML1 set during the second temperature measurement operation. The first ground level VOGD1 may be included in the first temperature table TEMPTB1. For example, the first ground level VOGD1 may be a level (TML1−VREF1) in which the first reference voltage VREF1 is subtracted from the first temperature operation level TML1 because it is expected that the first temperature operation level TML1 set during the second temperature measurement operation is higher than the level of the first reference voltage VREF1 set during the first temperature measurement operation.

In this case, the first temperature operation level TML1 set during the second temperature measurement operation may be a level in which the threshold voltage level (Vth(P2)) of the PMOS transistor P2 included in the second PMOS source-follower circuit 324 is added to the level of the first reference voltage VREF1. Because the first PMOS source-follower circuit 321 is set in the first measurement preparation state during each of the first temperature measurement operation and the second temperature measurement operation, the threshold voltage level (Vth(P1)) of the PMOS transistor P1 included in the first PMOS source-follower circuit 321 and the threshold voltage level (Vth(P2)) of the PMOS transistor P2 included in the second PMOS source-follower circuit 324 may be the same.

Accordingly, the first ground level VOGD1 calculated as the difference (TML1−VREF1 or VREF1−TML1) between the level of the first reference voltage VREF1 and the first temperature operation level TML1 during the first table generation operation may be the same as the threshold voltage level (Vth(P1)) of the PMOS transistor P1 included in the first PMOS source-follower circuit 321.

The test system may repeat the first temperature measurement operation, the second temperature measurement operation, and the first table generation operation through the test device 30 whenever the test system changes a temperature of the semiconductor device 32 as described above. Accordingly, after the test system intentionally changes a temperature of the semiconductor device 32 for N times, when the test device 30 repeats the first temperature measurement operation, the second temperature measurement operation, and the first table generation operation for N times, N first ground levels VOGD1<1:N> corresponding to the N temperatures, respectively, may be calculated. That is, the test system may calculate a difference (TML1<1:N>−VREF1<1:N> or VREF1<1:N> TML1<1:N>) between the N levels of the first reference voltage VREF1 set during the first temperature measurement operation that has been repeated N times and the N first temperature operation levels TML1 set during the second temperature measurement operation that has been repeated N times as N first ground levels VOGD1<1:N>, and may include the N first ground levels VOGD1<1:N> in the first temperature table TEMPTB1 (TEMPTB1{VOGD1<1:N>}). In this case, the N first ground levels VOGD1<1:N> may be the threshold voltage levels (Vth(P1)) of the PMOS transistor P1 included in the first PMOS source-follower circuit 321 that correspond to the N temperatures, respectively.

The test system may generate the first temperature table TEMPTB1 including the N first ground levels VOGD1<1:N> according to the N temperature variations by repeatedly performing the temperature measurement operation through the test device 30 while intentionally changing a temperature of the semiconductor device 32 as described above.

Thereafter, the test system may perform a test operation on the semiconductor device 32 through the test device 30. The test operation that is performed after the first temperature table TEMPTB1 is generated may be a test operation that is performed in the state (or mode) in which a temperature variation of the semiconductor device 32 has been incorporated.

Put another way, in the temperature incorporation mode, the test operation is performed in the state in which the N first ground levels VOGD1<1:N> according to the temperature variations of the semiconductor device 32 have been included in the first temperature table TEMPTB1 as described above prior to the execution of the test operation. Accordingly, during the test operations performed in the temperature incorporation mode, the test device 30 might not perform a first level measurement operation, that is, an operation of setting the level of the ground voltage (VSS) stage that is connected to the first target circuit 322 as the first ground level VOGD1 in the state in which the first target circuit 322 has been disabled.

Furthermore, during a test operation that is performed in the temperature incorporation mode, the test device 30 may perform a first level search operation instead of a first level measurement operation. That is, the test device 30 may perform a first level search operation of checking a current temperature of the semiconductor device 32 and determining the first ground level VOGD1 by searching the first temperature table TEMPTB1 for the checked temperature. In this case, the test device 30 may select any one first ground level VOGD1 (selecting one of TEMPTB1{VOGD1<1:N>}), among the N first ground levels VOGD1<1:N> according to the current temperature of the semiconductor device 32 because the N first ground levels VOGD1<1:N> are included in the first temperature table TEMPTB1.

Furthermore, when performing a test operation on the semiconductor device 32 in the temperature incorporation mode, the test device 30 may connect the ground voltage (VSS) stage, which is connected to the first target circuit 322, to the first input stage IN1 of the first PMOS source-follower circuit 321 and connect the measurement pad DPAD to the first output stage OUT1 of the first PMOS source-follower circuit 321 in the state in which the first target circuit 322 included in the semiconductor device 32 has been enabled in order to perform a second level measurement operation. To this end, the test device 30 may set the value of the test control signal TESC as “ENA” (TESC:ENA) and output the value “ENA” to the semiconductor device 32. Furthermore, in response to the test control signal TESC set as the value “ENA”, the operation control unit 323 included in the semiconductor device 32 may enable the first target circuit 322 by enabling (ENABLE) the enable signal EN, may connect the measurement pad DPAD to the first output stage OUT1 of the first PMOS source-follower circuit 321 by enabling (ON) the first test signal TC1, may connect the ground voltage (VSS) stage that is connected to the first target circuit 322 to the first input stage IN1 of the first PMOS source-follower circuit 321 by enabling (ON) the second test signal TC2, and might not connect the second input stage IN2 of the second PMOS source-follower circuit 324 and the second output stage OUT2 to the measurement pad DPAD by disabling (OFF) the fourth test signal TC4 and the fifth test signal TC5. Accordingly, the level of the ground voltage (VSS) stage that is connected to the first target circuit 322 in the enable state may be output to the measurement pad DPAD with almost no voltage change when passing through the first PMOS source-follower circuit 321.

More specifically, the first PMOS source-follower circuit 321 may include a PMOS transistor P1 having a gate connected to the first input stage IN1, a drain connected to the ground voltage (VSS) stage, and a source connected to the first output stage OUT1 and a current source IS1 that is connected between a source voltage (VDD) stage and the PMOS transistor P1.

In this case, in the enable state the first PMOS source-follower circuit 321 may transfer a level (ENAVSS+Vth(P1)) in which the threshold voltage level (Vth(P1)) of the PMOS transistor P1 is added to the level ENAVSS of the ground voltage (VSS) stage, to the first output stage OUT1.

Accordingly, in the enable state, a second ground level VOGD2 that is received by the test device 30 from the semiconductor device 32 as the result of the second level measurement operation may be the level (ENAVSS+Vth(P1)) in which the threshold voltage level (Vth(P1)) of the PMOS transistor P1 included in the first PMOS source-follower circuit 321 is added to the level ENAVSS of the ground voltage (VSS) stage, which is connected to the first target circuit 322.

Furthermore, when performing a test operation on the semiconductor device 32 in the temperature incorporation mode, the test device 30 may perform a first calculation operation after completing the execution of the first level search operation and the second level measurement operation. Specifically, to determine a ground variation level FRGD, the test device 30 may perform the first calculation operation of calculating a difference between the first ground level selected from the first temperature table TEMPTB1 (selecting one of TEMPTB1{VOGD1<1:N>}) during the first level search operation and the second ground level VOGD2 set during the second level measurement operation.

In this case, the first ground level selected from the first temperature table TEMPTB1 (selecting one of TEMPTB1{VOGD1<1:N>}) during the first level search operation may be a threshold voltage level (Vth(P1)) of the PMOS transistor P1 included in the first PMOS source-follower circuit 321, which corresponds to a current temperature of the semiconductor device 32. Furthermore, the second ground level VOGD2 set during the second level measurement operation may be the level (ENAVSS+Vth(P1)) in which the threshold voltage level (Vth(P1)) of the PMOS transistor P1 included in the first PMOS source-follower circuit 321 is added to the level ENAVSS of the ground voltage (VSS) stage, which is connected to the first target circuit 322 in the enable state.

Accordingly, the ground variation level FRGD indicative of the difference between the first ground level selected from the first temperature table TEMPTB1 (selecting one of TEMPTB1{VOGD1<1:N>}) during the first level search operation and the second ground level VOGD2 set during the second level measurement operation may be the same as the level ENAVSS of the ground voltage (VSS) stage, which is connected to the first target circuit 322 in the enable state.

Furthermore, after measuring the ground variation level FRGD by performing the test operation on the semiconductor device 32 in the temperature incorporation mode, the test system may perform a normal operation on the semiconductor device 32. That is, the semiconductor device 32 may adjust execution conditions for a preset internal operation to be performed within the semiconductor device with reference to the ground variation level FRGD after the start of the normal operation. For example, assuming that the semiconductor device 32 is a semiconductor memory device and the first target circuit 322 is a PLL circuit, the semiconductor device 32 may adjust the frequency offset of a clock generated by the PLL circuit with reference to the ground variation level FRGD.

Alternatively, as described above with reference to the semiconductor device 32 disclosed in FIGS. 3A to 3D, the test system may perform the test operation on the semiconductor device 32 in a temperature non-incorporation mode instead of a temperature incorporation mode as in the method described with reference to FIGS. 2A to 2C.

That is, in order not to generate and use the first temperature table TEMPTB1 according to temperature variations with respect to the semiconductor device 32 disclosed in FIGS. 3A to 3D, the test system might not perform operations related to the second PMOS source-follower circuit 324, that is, the first temperature measurement operation, the second temperature measurement operation, the first table generation operation, and the first level search operation through the test device 30. Instead, the test system may measure the ground variation level FRGD by performing a simpler test operation, that is, by only performing the first level measurement operation, the second level measurement operation, and the first calculation operation, on the semiconductor device 32 disclosed in FIGS. 3A to 3D in the temperature non-incorporation mode, using a method described with reference to FIGS. 2A to 2C.

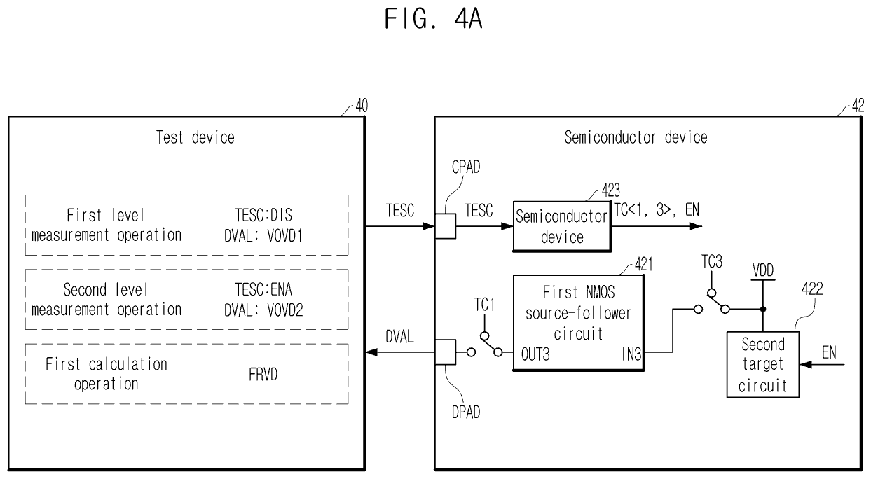

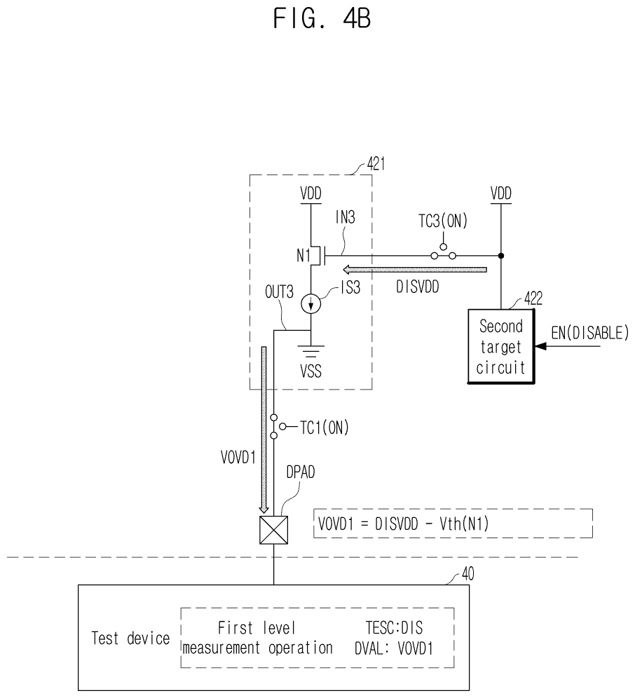

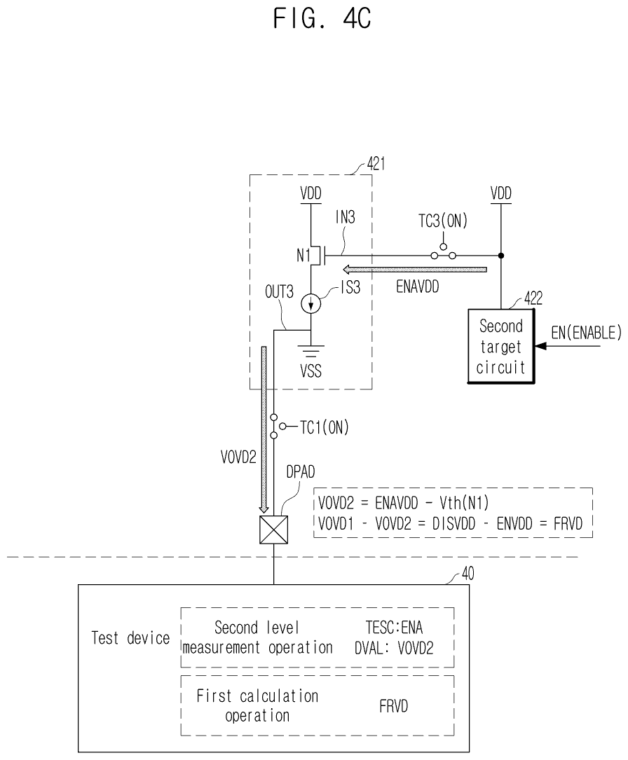

FIGS. 4A to 4C are diagrams illustrating an example of a test operation using an NMOS source-follower circuit in a semiconductor device and measuring a variation in the level of a source voltage according to an embodiment of the present disclosure.

In FIGS. 4A to 4C, a source-follower circuit 121 disclosed in FIG. 1 is an NMOS source-follower circuit that measures the level of a source voltage (VDD) stage. That is, FIGS. 4A to 4C illustrate an NMOS source-follower circuit used in the source-follower circuit 121 of FIG. 1 to accurately transfer the level of the source voltage (VDD) stage.

First, referring to FIG. 4A, a semiconductor device 42 may include a second target circuit 422, a first NMOS source-follower circuit 421, and an operation control unit 423.

In FIG. 4A, the second target circuit 422 is connected to the source voltage (VDD) stage, and may perform a preset operation in the enable state.

Furthermore, a third input stage IN3 of the first NMOS source-follower circuit 421 and the source voltage (VDD) stage that is connected to the second target circuit 422 may be selectively connected. A measurement pad DPAD and a third output stage OUT3 of the first NMOS source-follower circuit 421 may be selectively connected.

The operation control unit 423 may control operations of the second target circuit 422 and the first NMOS source-follower circuit 421 in response to a test control signal TESC that is input from the outside of the semiconductor device 42. For example, the operation control unit 423 may control operations of the second target circuit 422 and the first NMOS source-follower circuit 421 in response to the test control signal TESC that is received from a test device 40.

For example, the operation control unit 423 may enable or disable operations of the second target circuit 422 in response to the test control signal TESC. Furthermore, the operation control unit 423 may connect or may not connect the source voltage (VDD) stage that is connected to the second target circuit 422 to the third input stage IN3 of the first NMOS source-follower circuit 421 in response to the test control signal TESC. In addition, the operation control unit 423 may connect or may not connect the third output stage OUT3 of the first NMOS source-follower circuit 421 to a measurement pad DPAD in response to the test control signal TESC.

For reference, the second target circuit 422 illustrated in FIG. 4A may be the same circuit as the target circuit 122 illustrated in FIG. 1 or may be a circuit different from the target circuit 122 illustrated in FIG. 1. That is, the second target circuit 422 illustrated in FIG. 4A refers to a circuit selected as the target of an operation of transferring the level of the source voltage (VDD) stage connected to the second target circuit 422 to the measurement pad DPAD without minimal voltage change through the first NMOS source-follower circuit 421, and as such the target circuit is not limited to a specific type of circuit. Accordingly, although not illustrated, a ground voltage (VSS) stage may be connected to the second target circuit 422, but may be in the state in which the ground voltage (VSS) stage has not been selected as a target to be measured.

A test system including the test device 40 and the semiconductor device 42 may perform a test operation on the semiconductor device 42 as follows.

Referring to both FIGS. 4A and 4B, when performing a test operation on the semiconductor device 42, in a first level measurement operation the test device 40 may connect the source voltage (VDD) stage, which is connected to the second target circuit 422, to the third input stage IN3 of the first NMOS source-follower circuit 421, and may connect the measurement pad DPAD to the third output stage OUT3 of the first NMOS source-follower circuit 421 in the state in which the second target circuit 422 included in the semiconductor device 42 has been disabled. To this end, the test device 40 may set the value of the test control signal TESC as “DIS” (TESC:DIS) and output the value “DIS” to the semiconductor device 42. Furthermore, in response to the test control signal TESC set as the value “DIS”, the operation control unit 423 included in the semiconductor device 42 may disable the second target circuit 422 by disabling (DISABLE) an enable signal EN, may connect the measurement pad DPAD to the third output stage OUT3 of the first NMOS source-follower circuit 421 by enabling (ON) a first test signal TC1, and may connect the source voltage (VDD) stage that is connected to the second target circuit 422 to the third input stage IN3 of the first NMOS source-follower circuit 421 by enabling (ON) a third test signal TC3. Accordingly, the level of the source voltage (VDD) stage that is connected to the second target circuit 422 in the disable state may be output to the measurement pad DPAD nearly without voltage changes through the first NMOS source-follower circuit 421.

More specifically, the first NMOS source-follower circuit 421 may include an NMOS transistor N1 having a gate connected to the third input stage IN3, a drain connected to the source voltage (VDD) stage, and a source connected to the third output stage OUT3 and a current source IS3 that is connected between a ground voltage (VSS) stage and the source of the NMOS transistor N1. For reference, the current source IS3 is a circuit that stably operates the NMOS transistor N1 in an active area by controlling the NMOS transistor N1 so that a drain current having a preset size flows in a direction from the source of the NMOS transistor N1 to the drain of the NMOS transistor N1. A detailed construction of the current source IS3 is an already known technology, and thus will not be described hereinafter in detail.

The first NMOS source-follower circuit 421 may transfer a level (DISVDD−Vth(N1)) in which the threshold voltage level (Vth(N1)) of the NMOS transistor N1 is subtracted from the level DISVDD of the source voltage (VDD) stage to the third output stage OUT3.

Accordingly, a first power supply level VOVD1 that is received by the test device 40 from the semiconductor device 42 as the result of the first level measurement operation may be the level (DISVDD−Vth(N1)) in which the threshold voltage level (Vth(N1)) of the NMOS transistor N1 included in the first NMOS source-follower circuit 421 is subtracted from the level DISVDD of the source voltage (VDD) stage, which is connected to the second target circuit 422 in the disable state.

Furthermore, referring to both FIGS. 4A and 4C, when performing a test operation on the semiconductor device 42, when the second target circuit 422 is enabled, the test device 40 may connect the source voltage (VDD) stage that is connected to the second target circuit 422 to the third input stage IN3 of the first NMOS source-follower circuit 421 and connect the measurement pad DPAD to the third output stage OUT3 of the first NMOS source-follower circuit 421 in order to perform a second level measurement operation. To this end, the test device 40 may set the value of the test control signal TESC as “ENA” (TESC:ENA) and output the value “ENA” to the semiconductor device 42. Furthermore, in response to the test control signal TESC set as the value “ENA”, the operation control unit 423 included in the semiconductor device 42 may enable the second target circuit 422 by enabling (ENABLE) the enable signal EN, may connect the measurement pad DPAD to the third output stage OUT3 of the first NMOS source-follower circuit 421 by enabling (ON) the first test signal TC1, and may connect the source voltage (VDD) stage that is connected to the second target circuit 422 to the third input stage IN3 of the first NMOS source-follower circuit 421 by enabling (ON) the third test signal TC3. Accordingly, the level of the source voltage (VDD) stage, which is connected to the second target circuit 422 in the enable state, may be output to the measurement pad DPAD with hardly any change through the first NMOS source-follower circuit 421.

More specifically, the first NMOS source-follower circuit 421 may include an NMOS transistor N1 having a gate connected to the third input stage IN3, a drain connected to the source voltage (VDD) stage, and a source connected to the third output stage OUT3 and a current source IS3 that is connected between the ground voltage (VSS) stage and the source of the NMOS transistor N1.

The first NMOS source-follower circuit 421 may transfer a level (ENAVDD−Vth(N1)) in which the threshold voltage level (Vth(N1)) of the NMOS transistor N1 is subtracted from the level ENAVDD of the source voltage (VDD) stage to the third output stage OUT3.

Accordingly, a second power supply level VOVD2, which is received by the test device 40 from the semiconductor device 42 as the result of the second level measurement operation, may be the level (ENAVDD−Vth(N1)) in which the threshold voltage level (Vth(N1)) of the NMOS transistor N1 included in the first NMOS source-follower circuit 421 is subtracted from the level ENAVDD of the source voltage (VDD) stage that is connected to the second target circuit 422 in the enable state.

Furthermore, after completing the execution of the first level measurement operation and the second level measurement operation, the test device 40 may perform a first calculation operation. Specifically, the test device 40 may perform the first calculation operation of calculating a difference between the first power supply level VOVD1 set during the first level measurement operation and the second power supply level VOVD2 set during the second level measurement operation as a power supply variation level FRVD.

The first power supply level VOVD1 set during the first level measurement operation may be the level (DISVDD−Vth(N1)) in which the threshold voltage level (Vth(N1)) of the NMOS transistor N1 included in the first NMOS source-follower circuit 421 is subtracted from the level DISVDD of the source voltage (VDD) stage that is connected to the second target circuit 422 in the disable state. Furthermore, the second power supply level VOVD2 set during the second level measurement operation may be the level (ENAVDD−Vth(N1)) in which the threshold voltage level (Vth(N1)) of the NMOS transistor N1 included in the first NMOS source-follower circuit 421 is subtracted from the level ENAVDD of the source voltage (VDD) stage that is connected to the second target circuit 422 in the enable state.

Accordingly, the power supply variation level FRVD indicative of the difference between the first power supply level VOVD1 set during the first level measurement operation and the second power supply level VOVD2 set during the second level measurement operation may be a level (ENVDD DISVDD or DISVDD-ENVDD) indicative of a difference between the level ENAVDD of the source voltage (VDD) stage that is connected to the second target circuit 422 in the enable state and the level DISVDD of the source voltage (VDD) stage that is connected to the second target circuit 422 in the disable state. For example, the power supply variation level FRVD may be a level (DISVDD−ENVDD) in which the level ENAVDD of the source voltage (VDD) stage that is connected to the second target circuit 422 in the enable state is subtracted from the level DISVDD of the source voltage (VDD) stage that is connected to the second target circuit 422 in the disable state because it is expected that the first power supply level VOVD1 set during the first level measurement operation is higher than the second power supply level VOVD2 set during the second level measurement operation.

In other words, through the first level measurement operation, the test device 40 may receive the level of the source voltage (VDD) stage with de minimis, if any, changes in voltage through the measurement pad DPAD and measure the level of the source voltage (VDD) stage as the first power supply level VOVD1 when the second target circuit 422 included in the semiconductor device 42 is in the disable state.

Furthermore, through the second level measurement operation, the test device 40 may receive the level of the source voltage (VDD) stage without almost any change through the measurement pad DPAD and measure the level of the source voltage (VDD) stage as the second power supply level VOVD2 when the second target circuit 422 included in the semiconductor device 42 is in the enable state.

Furthermore, to determine the power supply variation level FRVD, the test device 40 may perform the first calculation operation of calculating a difference between the first power supply level VOVD1 and the second power supply level VOVD2, which the results of the execution of the first level measurement operation and the second level measurement operation.

After measuring the power supply variation level FRVD by performing a test operation on the semiconductor device 42, the test system may perform a normal operation on the semiconductor device 42. That is, after the start of the normal operation, the semiconductor device 42 may adjust execution conditions for a preset internal operation to be performed within the semiconductor device with reference to the power supply variation level FRVD. For example, assuming that the semiconductor device 42 is a semiconductor memory device and the second target circuit 422 is a PLL circuit, the semiconductor device 42 may adjust the frequency offset of a clock generated by the PLL circuit with reference to the power supply variation level FRVD.

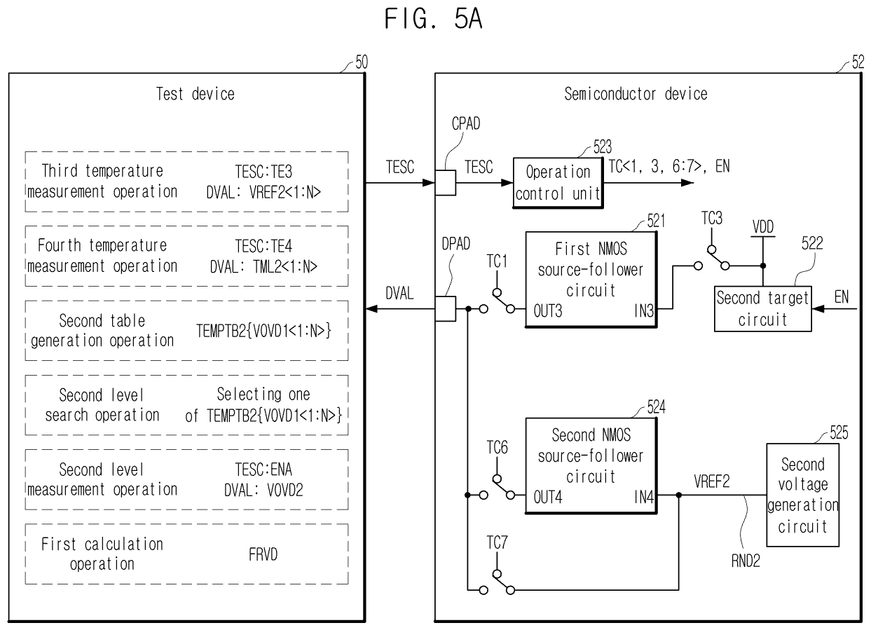

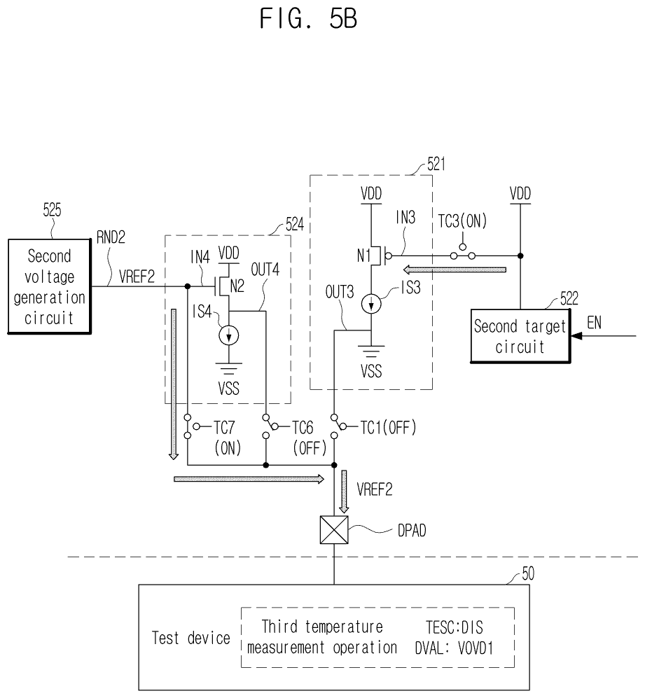

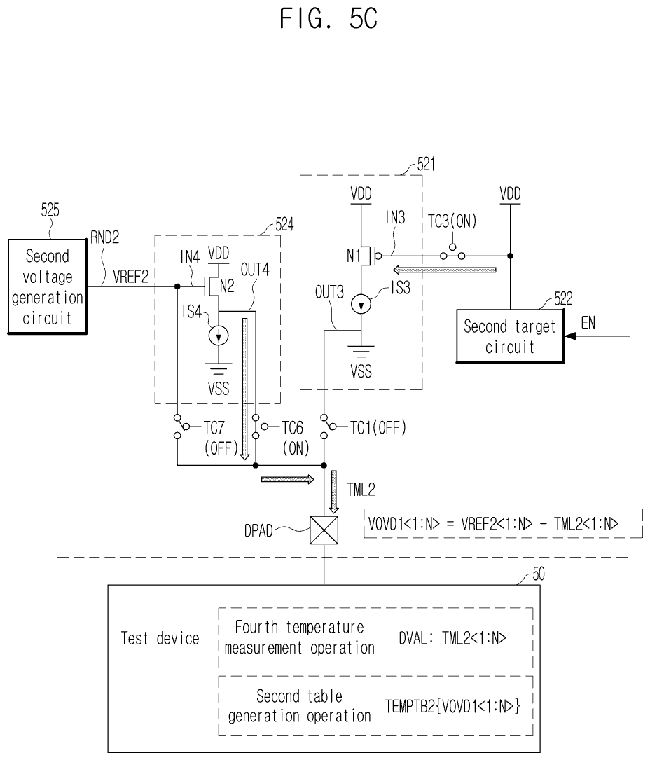

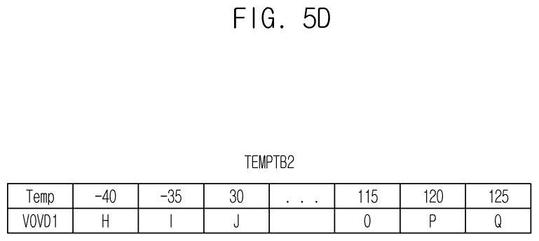

FIGS. 5A to 5D are diagrams illustrating an example of a test operation using an NMOS source-follower circuit in a semiconductor device and measuring a variation in the level of a source voltage corresponding to temperature variation according to an embodiment of the present disclosure.

In FIGS. 4A to 4C, only a test operation capable of measuring the level of the source voltage (VDD) stage at a current time without accounting to temperature variation of a semiconductor device 52 (the temperature non-incorporation mode) by using the temperature variation as a variable has been described. Hereinafter, a test operation capable of measuring a variation in the level of the source voltage (VDD) stage according to a temperature variation of the semiconductor device 52 by incorporating temperature variation as a variable (the temperature incorporation mode) will be described with reference to FIGS. 5A to 5D.

Referring to FIG. 5A, the semiconductor device 52 may include a second target circuit 522, a first NMOS source-follower circuit 521, a second NMOS source-follower circuit 524, a second voltage generation circuit 525, and an operation control unit 523.

The second target circuit 522 is connected to the source voltage (VDD) stage, and may perform a preset operation in the enable state.

Furthermore, a third input stage IN3 of the first NMOS source-follower circuit 521 and the source voltage (VDD) stage that is connected to the second target circuit 522 may be selectively connected. A measurement pad DPAD and a third output stage OUT3 of the first NMOS source-follower circuit 521 may be selectively connected.

The second voltage generation circuit 525 may generate a second reference voltage VREF2 and supply the second reference voltage VREF2 to a second reference voltage stage RND2. For example, the second voltage generation circuit 525 may include a bandgap reference circuit, and may be a circuit that operates so that the level of the second reference voltage VREF2 can maintain a preset level regardless of a temperature variation. However, the level of the second reference voltage VREF2 may slightly change on the basis of the preset level with temperature variation because the bandgap reference circuit included in the second voltage generation circuit 525 is a circuit component that operates by including a diode and a CMOS transistor. That is, maintaining the level of the second reference voltage VREF2 at a preset level regardless of device temperature variation merely means that although temperature variation occurs, the level of the second reference voltage VREF2 maintains a level that does not greatly vary from the preset level, and this does not mean that the level of the second reference voltage VREF2 never changes. A detailed construction of the bandgap reference circuit is already known technology, and thus will not be described in detail.

Furthermore, a fourth input stage IN4 of the second NMOS source-follower circuit 524, which is connected to the second reference voltage stage RND2, may be selectively connected to the measurement pad DPAD. A fourth output stage OUT4 of the second NMOS source-follower circuit 524 may be selectively connected to the measurement pad DPAD.

The operation control unit 523 may control operations of the second target circuit 522, the first NMOS source-follower circuit 521, and the second NMOS source-follower circuit 524 in response to a test control signal TESC that is input from the outside of the semiconductor device 52. That is, the operation control unit 523 may control operations of the second target circuit 522, the first NMOS source-follower circuit 521, and the second NMOS source-follower circuit 524 in response to the test control signal TESC received from a test device 50.

For example, the operation control unit 523 may enable or disable an operation of the second target circuit 522 in response to the test control signal TESC. Furthermore, the operation control unit 523 may connect or may not connect the source voltage (VDD) stage that is connected to the second target circuit 522 to the third input stage IN3 of the first NMOS source-follower circuit 521 in response to the test control signal TESC. Furthermore, the operation control unit 523 may connect or may not connect the third output stage OUT3 of the first NMOS source-follower circuit 521 to the measurement pad DPAD in response to the test control signal TESC. In addition, the operation control unit 523 may connect or may not connect the fourth input stage IN4 of the second NMOS source-follower circuit 524, which is connected to the second reference voltage stage RND2, to the measurement pad DPAD in response to the test control signal TESC. Further still, the operation control unit 523 may connect or may not connect the fourth output stage OUT4 of the second NMOS source-follower circuit 524 to the measurement pad DPAD in response to the test control signal TESC.

A test system including the test device 50 and the semiconductor device 52 may generate a second temperature table TEMPTB2 including a first power supply level VOVD1 according to the temperature variation of the semiconductor device 52 repeatedly performing a temperature measurement operation according to device temperature variation as follows before performing a test operation on the semiconductor device 52. That is, the test system may generate the second temperature table TEMPTB2 including the first power supply level VOVD1 according to the temperature variation in the device by repeatedly performing the temperature measurement operations using the test device 50 while intentionally changing the temperature of the semiconductor device 52.

The test system may intentionally change a temperature of the semiconductor device 52. For example, as illustrated in FIG. 5D, the test system may change the temperature of a semiconductor device 52 at intervals of 5 °C from −40 °C to 125 °C. Thus, the test system may repeat a third temperature measurement operation, a fourth temperature measurement operation, and a second table generation operation through the test device 50 whenever the test system changes the temperature of the semiconductor device 52. For example, after changing the temperature of the semiconductor device 52 to the temperature of −40 °C, the test system may calculate “H”, that is, a value of the first power supply level VOVD1 corresponding to the temperature of −40 °C, by performing a third temperature measurement operation, the fourth temperature measurement operation, and the second table generation operation through the test device 50, and may include the value “H” in the second temperature table TEMPTB2. As another example, after changing the temperature of the semiconductor device 52 to 125 °C, the test system may calculate “Q”, that is, a value of the first power supply level VOVD1 corresponding to the temperature of 125 °C, by performing the third temperature measurement operation, the fourth temperature measurement operation, and the second table generation operation through the test device 50, and may include the value “Q” in the second temperature table TEMPTB2.

Specifically, referring to FIGS. 5A and 5B, in order to perform the third temperature measurement operation, the test device 50 may connect the source voltage (VDD) stage, which is connected to the second target circuit 522, to the third input stage IN3 of the first NMOS source-follower circuit 521. The measurement pad DPAD is not connected to the third output stage OUT3 of the first NMOS source-follower circuit 521. Thus, these elements are placed in a second measurement preparation state with respect to each other.

Furthermore, in order to perform the third temperature measurement operation, the test device 50 may transfer the second reference voltage VREF2 loaded onto the second reference voltage stage RND2 to the measurement pad DPAD without connecting the measurement pad DPAD and the fourth output stage OUT4 of the second NMOS source-follower circuit 524 and by connecting the fourth input stage IN4 of the second NMOS source-follower circuit 524 to the measurement pad DPAD.

To this end, the test device 50 may set the value of the test control signal TESC as “TE3” (TESC:TE3) and output the value “TE3” to the semiconductor device 52.

Furthermore, the operation control unit 523 included in the semiconductor device 52 may disable (OFF) a first test signal TC1 so that the measurement pad DPAD is not connected to the third output stage OUT3 of the first NMOS source-follower circuit 521 and enable (ON) a third test signal TC3 so that the source voltage (VDD) stage that is connected to the second target circuit 522 is connected to the third input stage IN3 of the first NMOS source-follower circuit 521 in response to the test control signal TESC set as the value “TE3”.

In response to the test control signal TESC set as the value “TE3”, the operation control unit 523 included in the semiconductor device 52 might not connect the measurement pad DPAD to the fourth output stage OUT4 of the second NMOS source-follower circuit 524 by disabling (OFF) a sixth test signal TC6, and may connect the fourth input stage IN4 of the second NMOS source-follower circuit 524, which is connected to the second reference voltage stage RND2, to the measurement pad DPAD by enabling (ON) a seventh test signal TC7.

Accordingly, the test device 50 may receive the second reference voltage VREF2 through the measurement pad DPAD during the third temperature measurement operation.

More specifically, the second NMOS source-follower circuit 524 may include an NMOS transistor N2 having a gate connected to the fourth input stage IN4 that is connected to the second reference voltage (VREF2) stage, a drain connected to the source voltage (VDD) stage, and a source connected to the fourth output stage OUT4, and a current source IS4 that is connected between the ground voltage (VSS) stage and the source of the NMOS transistor N2. For reference, the current source IS4 is a circuit that stably operates the NMOS transistor N2 in an active area by controlling the NMOS transistor N2 so that a drain current having a preset size flows in the direction of the drain of the NMOS transistor N2 from the source of the NMOS transistor N2. A detailed construction of the current source IS4 is already known technology, and thus will not be described hereinafter in detail.

When repeating a third temperature measurement operation for the semiconductor device 52 using the test device 50 after intentionally changing a temperature of the semiconductor device 52 for N times as described above, the test system may measure N levels (VREF2<1:N>) of the second reference voltage VREF2 corresponding to the N temperatures, respectively, where N is a natural number equal or greater than 2.

For example, when performing the third temperature measurement operation on the semiconductor device 52 in the state in which a temperature of the semiconductor device 52 has been changed to −30 °C, the test system may measure a level of the second reference voltage VREF2 corresponding to the temperature of −30 °C. As another example, when performing the third temperature measurement operation on the semiconductor device 52 when a temperature of the semiconductor device 52 has been changed into −115 °C, the test system may measure a level of the second reference voltage VREF2 orresponding to the temperature of 115.

The test device 50 measures N levels (VREF2<1:N>) of the second reference voltage VREF2 corresponding to the N temperatures, respectively, by repeating the third temperature measurement operation as described above by assuming that the level of the second reference voltage VREF2 only slightly changes from a preset level because the bandgap reference circuit included in the second voltage generation circuit 525 is a circuit component that operates by with a diode and a CMOS transistor.

Referring to FIGS. 5A and 5C, in order to perform the fourth temperature measurement operation, the test device 50 may set the second target circuit 522, the first NMOS source-follower circuit 521 and the measurement pad DPAD in the second measurement preparation state, which is described above in connection with the third temperature measurement operation.

In the fourth temperature measurement operation, the test device 50 does not connect the fourth input stage IN4 of the second NMOS source-follower circuit 524, which is connected to the second reference voltage stage RND2, to the measurement pad DPAD. The test device 50 may connect the measurement pad DPAD and the fourth output stage OUT4 of the second NMOS source-follower circuit 524.

To this end, the test device 50 may set the value of the test control signal TESC as “TE4” (TESC:TE4) and output the value “TE4” to the semiconductor device 52.

The operation control unit 523 included in the semiconductor device 52 may disable (OFF) the first test signal TC1 so that the measurement pad DPAD is not connected to the third output stage OUT3 of the first NMOS source-follower circuit 521 and may enable (ON) the third test signal TC3 so that the source voltage (VDD) stage, which is connected to the second target circuit 522, is connected to the third input stage IN3 of the first NMOS source-follower circuit 521 in response to the test control signal TESC, which is set as the value “TE4”.

In response to the test control signal TESC set as the value “TE4”, the operation control unit 523 included in the semiconductor device 52 may connect the measurement pad DPAD to the fourth output stage OUT4 of the second NMOS source-follower circuit 524 by enabling (ON) the sixth test signal TC6, and might not connect the fourth input stage IN4 of the second NMOS source-follower circuit 524, which is connected to the second reference voltage stage RND2, to the measurement pad DPAD by disabling (OFF) the seventh test signal TC7.

Accordingly, a level VREF2−Vth(N2)) in which the threshold voltage level (Vth(N2)) of the NMOS transistor N2 included in the second NMOS source-follower circuit 524 is subtracted from the level of the second reference voltage VREF2 loaded onto the second reference voltage stage RND2 may be output to the measurement pad DPAD. That is, in the fourth temperature measurement operation, the test device 50 may receive a second temperature operation level TML2 that is lower than the level of the second reference voltage VREF2 by the threshold voltage level (Vth(N2)) of the NMOS transistor from the measurement pad DPAD.

More specifically, the second NMOS source-follower circuit 524 may include an NMOS transistor N2 having a gate connected to the fourth input stage IN4 that is connected to the second reference voltage (VREF2) stage, a drain connected to the source voltage (VDD) stage, and a source connected to the fourth output stage OUT4, and a current source IS4 that is connected between the ground voltage (VSS) stage and the source of the NMOS transistor N2.

When repeating the fourth temperature measurement operation for the semiconductor device 52 using the test device 50 after intentionally changing a temperature of the semiconductor device 52 for N times as described above, the test system may measure N levels (VML1<1:N>) of the second temperature operation level TML2 corresponding to the N temperatures, respectively, where N is a natural number equal or greater than 2.

For example, when performing a fourth temperature measurement operation on a semiconductor device 52 in the state in which a temperature of the semiconductor device 52 has been changed to −30 °C, the test system may measure a level of the second temperature operation level TML2 corresponding to the temperature of −30 °C. As another example, when performing the fourth temperature measurement operation on the semiconductor device 52 when a temperature of the semiconductor device 52 has changed to −115 °C, the test system may measure a level of the second temperature operation level TML2 corresponding to the temperature of 115 °C.

When the test device 50 performs third and fourth temperature measurement operations on the second NMOS source-follower circuit 524, the state of the first NMOS source-follower circuit 521 is in the second measurement preparation state. As a result, both the NMOS transistor N1 included in the first NMOS source-follower circuit 521 and the NMOS transistor N2 included in the second NMOS source-follower circuit 524 have the same state, that is, a turn-on state, during the interval in which the third and fourth temperature measurement operations are performed. Accordingly, while the test device 50 performs the third temperature measurement operation and the fourth temperature measurement operation on the semiconductor device 52, the threshold voltage level (Vth(N1)) of the NMOS transistor N1 included in the first NMOS source-follower circuit 521 and the threshold voltage level (Vth(N2)) of the NMOS transistor N2 included in the second NMOS source-follower circuit 524 may have the same level.

Furthermore, after completing the execution of the third temperature measurement operation and the fourth temperature measurement operation, the test device 50 may perform the second table generation operation. Specifically, the test device 50 may calculate a first power supply level VOVD1, which is the difference (TML2−VREF2 or VREF2 TML2) between the level of the second reference voltage VREF2 set during the third temperature measurement operation and the second temperature operation level TML2 set during the fourth temperature measurement operation. The first power supply level VOVD1 may be included in the second temperature table TEMPTB2. For example, the first power supply level VOVD1 may be a level (VREF2−TML2) in which the second temperature operation level TML2 is subtracted from the second reference voltage VREF2 because it is expected that the second temperature operation level TML2 set during the fourth temperature measurement operation is lower than the level of the second reference voltage VREF2 set during the third temperature measurement operation.

In this case, the second temperature operation level TML2 set during the fourth temperature measurement operation may be a level in which the threshold voltage level (Vth(N2)) of the NMOS transistor N2 included in the second NMOS source-follower circuit 524 is subtracted from the level of the second reference voltage VREF2. Because the first NMOS source-follower circuit 521 is set in the second measurement preparation state during each of the third temperature measurement operation and the fourth temperature measurement operation, the threshold voltage level (Vth(N1)) of the NMOS transistor N1 included in the first NMOS source-follower circuit 521 and the threshold voltage level (Vth(N2)) of the NMOS transistor N2 included in the second NMOS source-follower circuit 524 may be the same.

Accordingly, the first power supply level VOVD1 that is calculated as the difference (TML2−VREF2 or VREF2−TML2) between the level of the second reference voltage VREF2 and the second temperature operation level TML2 during the second table generation operation may be the same as the threshold voltage level (Vth(N1)) of the NMOS transistor N1 included in the first NMOS source-follower circuit 521.

The test system may repeat the third temperature measurement operation, the fourth temperature measurement operation, and the second table generation operation through the test device 50 whenever the test system changes a temperature of the semiconductor device 52 as described above. Accordingly, after the test system intentionally changes a temperature of the semiconductor device 52 for N times, when the test device 50 repeats the third temperature measurement operation, the fourth temperature measurement operation, and the second table generation operation for N times, the test system may calculate N first power supply levels VOVD1<1:N> corresponding to the N temperatures, respectively. That is, the test system may calculate a difference (TML2<1:N>−VREF2<1:N> or VREF2<1:N>−TML2<1:N>) between N levels of the second reference voltage VREF2 set during the third temperature measurement operation that has been repeated N times and the N second temperature operation levels TML2 set during the fourth temperature measurement operation that has been repeated N times as N first power supply levels VOVD1<1:N>, and may include the N first power supply levels VOVD1<1:N> in the second temperature table TEMPTB2 (TEMPTB1{VOVD1<1:N>}). In this case, the N first power supply levels VOVD1<1:N> may be the threshold voltage levels (Vth(N1)) of the NMOS transistor N1 included in the first NMOS source-follower circuit 521 that correspond to the N temperatures, respectively.

The test system may generate the second temperature table TEMPTB2 including the N first power supply levels VOVD1<1:N> according to the N temperature variations by repeatedly performing the temperature measurement operation through the test device 50 while intentionally changing a temperature of the semiconductor device 52 as described above.

Thereafter, the test system may perform a test operation on the semiconductor device 52 through the test device 50. The test operation that is performed after the second temperature table TEMPTB2 is generated may be a test operation that is performed in the state (or mode) in which the temperature variations of the semiconductor device 52 have been incorporated.

Put another way, in the temperature incorporation mode, the test operation is performed in the state in which the N first power supply levels VOVD1<1:N> according to the temperature variations of the semiconductor device 52 have been included in the second temperature table TEMPTB2 as described above prior to the execution of the test operation. Accordingly, during the test operations performed in the temperature incorporation mode, the test device 50 might not perform a first level measurement operation, that is, an operation of setting the level of the source voltage (VDD) stage that is connected to the second target circuit 522 as the first power supply level VOVD1 in the state in which the second target circuit 522 has been disabled.

Furthermore, during a test operation that is performed in the temperature incorporation mode, the test device 50 may perform a second level search operation instead of a first level measurement operation. That is, the test device 50 may perform a second level search operation of checking a current temperature of the semiconductor device 52 and determining the first power supply level VOVD1 by searching the second temperature table TEMPTB2 for the checked temperature. In this case, the test device 50 may select any one first power supply level VOVD1 (selecting one of TEMPTB1{VOVD1<1:N>}), among the N first power supply levels VOVD1<1:N>, based on the current temperature of the semiconductor device 52 because the N first power supply levels VOVD1<1:N> are included in the second temperature table TEMPTB2.

Furthermore, when performing a test operation on the semiconductor device 52 in the temperature incorporation mode, the test device 50 may connect the source voltage (VDD) stage, which is connected to the second target circuit 522, to the third input stage IN3 of the first NMOS source-follower circuit 521 and connect the measurement pad DPAD to the third output stage OUT3 of the first NMOS source-follower circuit 521 in the state in which the second target circuit 522 included in the semiconductor device 52 has been enabled in order to perform a second level measurement operation. To this end, the test device 50 may set the value of the test control signal TESC as “ENA” (TESC:ENA) and output the value “ENA” to the semiconductor device 52. Furthermore, in response to the test control signal TESC set as the value “ENA”, the operation control unit 523 included in the semiconductor device 52 may enable the second target circuit 522 by enabling (ENABLE) an enable signal EN, may connect the measurement pad DPAD to the third output stage OUT3 of the first NMOS source-follower circuit 521 by enabling (ON) the first test signal TC1, may connect the source voltage (VDD) stage that is connected to the second target circuit 522 to the third input stage IN3 of the first NMOS source-follower circuit 521 by enabling (ON) the third test signal TC3, and might not connect the fourth input stage IN4 of the second NMOS source-follower circuit 524 and the fourth output stage OUT4 to the measurement pad DPAD by disabling (OFF) the sixth test signal TC6 and the seventh test signal TC7. Accordingly, the level of the source voltage (VDD) stage that is connected to the second target circuit 522 in the enable state may be output to the measurement pad DPAD with almost no change to voltage when passing through the first NMOS source-follower circuit 521.

More specifically, the first NMOS source-follower circuit 521 may include an NMOS transistor N1 having a gate connected to the third input stage IN3, a drain connected to the source voltage (VDD) stage, and a source connected to the third output stage OUT3, and a current source IS3 that is connected between the ground voltage (VSS) stage and the source of the NMOS transistor N1.

In this case, in the enable state the first NMOS source-follower circuit 521 may transfer a level (ENAVDD−Vth(N1)) in which the threshold voltage level (Vth(N1)) of the NMOS transistor N1 is subtracted from the level ENAVDD of the source voltage (VDD) stage, to the third output stage OUT3.

Accordingly, in the enable state, a second power supply level VOVD2 that is received by the test device 50 from the semiconductor device 52 as the result of the second level measurement operation may be the level (ENAVDD−Vth(N1)) in which the threshold voltage level (Vth(N1)) of the NMOS transistor N1 included in the first NMOS source-follower circuit 521 is subtracted from the level ENAVDD of the source voltage (VDD) stage, which is connected to the second target circuit 522.

Furthermore, when performing a test operation on the semiconductor device 52 in the temperature incorporation mode, the test device 50 may perform a first calculation operation after completing the execution of the second level search operation and the second level measurement operation. Specifically, to determine a power supply variation level FRVD, the test device 50 may perform the first calculation operation of calculating a difference between the first power supply level selected from the second temperature table TEMPTB2 (selecting one of TEMPTB1{VOVD1<1:N>}) during the second level search operation and the second power supply level VOVD2 set during the second level measurement operation.

In this case, the first power supply level selected from the second temperature table TEMPTB2 (selecting one of TEMPTB1{VOVD1<1:N>}) during the second level search operation may be a threshold voltage level (Vth(N1)) of the NMOS transistor N1 included in the first NMOS source-follower circuit 521, which corresponds to the current temperature of the semiconductor device 52. Furthermore, the second power supply level VOVD2 set during the second level measurement operation may be the level (ENAVDD−Vth(N1)) in which the threshold voltage level (Vth(N1)) of the NMOS transistor N1 included in the first NMOS source-follower circuit 521 is subtracted from the level ENAVDD of the source voltage (VDD) stage, which is connected to the second target circuit 522 in the enable state.

Accordingly, the power supply variation level FRVD indicative of the difference between the first power supply level selected from the second temperature table TEMPTB2 (selecting one of TEMPTB1{VOVD1<1:N>}) during the second level search operation and the second power supply level VOVD2 set during the second level measurement operation may be the same as the level ENAVDD of the source voltage (VDD) stage, which is connected to the second target circuit 522 in the enable state.

Furthermore, after measuring the power supply variation level FRVD by performing the test operation on the semiconductor device 5 in the temperature incorporation mode, the test system may perform a normal operation on the semiconductor device 52. That is, after the start of the normal operation, the semiconductor device 52 may adjust execution conditions for a preset internal operation to be performed within the semiconductor device with reference to the power supply variation level FRVD. For example, assuming that the semiconductor device 52 is a semiconductor memory device and the second target circuit 522 is a PLL circuit, the semiconductor device 52 may adjust the frequency offset of a clock generated by the PLL circuit with reference to the power supply variation level FRVD.

Alternatively, instead of operating the semiconductor device 52 disclosed in FIGS. 5A to 5D in the temperature incorporation mode as described above, the test system may perform a test operation on the semiconductor device 52 in without entering a temperature incorporation mode, which is a method described with reference to FIGS. 4A to 4C.

That is, in order not to generate and use the second temperature table TEMPTB2 according to the temperature variations with respect to the semiconductor device 52 disclosed in FIGS. 5A to 5D, the test system might not perform operations related to the second NMOS source-follower circuit 524, that is, the third temperature measurement operation, the fourth temperature measurement operation, the second table generation operation, and the second level search operation, through the test device 50. Instead, the test system may measure the power supply variation level FRVD by performing a simpler test operation, that is, by only performing the first level measurement operation, the second level measurement operation, and the first calculation operation, on the semiconductor device 52 disclosed in FIGS. 5A to 5D in a temperature non-incorporation mode, using a method described with reference to FIGS. 4A to 4C.

It will be evident to a person having ordinary knowledge in the art to which the present disclosure pertains that the present disclosure described above is not limited by the aforementioned embodiments and the accompanying drawings and that the present disclosure may be substituted, modified, and changed in various ways without departing from the technical spirit of the present disclosure.

For example, the locations and types of the logic gates and the transistors illustrated in the aforementioned embodiments have to be differently implemented depending on the polarity of an input signal.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A method of performing a test operation on a semiconductor device, the method comprising:
selectively connecting an input stage of a source-follower circuit to a target circuit, which is connected to a ground voltage stage or a source voltage stage to perform a preset operation in an enable state;
selectively connecting an output stage of the source-follower circuit to a measurement pad;
measuring, as a first level measurement operation, a first ground level or a first power supply level through the measurement pad in a state in which the target circuit is disabled;
measuring, as a second level measurement operation, a second ground level or a second power supply level through the measurement pad in a state in which the target circuit is enabled; and
calculating, as a first calculation operation, a difference between the first ground level and the second ground level as a ground variation level or a difference between the first power supply level and the second power supply level as a power supply variation level,
wherein the semiconductor device comprises the target circuit, the source-follower circuit and the measurement pad.

2. The method of claim 1, wherein when the source-follower circuit is a first PMOS source-follower circuit having a first input stage selectively connected to the ground voltage stage and having a first output stage selectively connected to the measurement pad,
the first level measurement operation comprises measuring the first ground level through the measurement pad in a state in which a first target circuit that is connected to the ground voltage stage is disabled,
the second level measurement operation comprises measuring the second ground level through the measurement pad in a state in which the first target circuit is enabled, and
the first calculation operation comprises calculating the difference between the first and second ground levels as the ground variation level.

3. The method of claim 2, wherein:
the semiconductor device further comprises a first voltage generation circuit configured to generate a first reference voltage and to supply the first reference voltage to a first reference voltage stage, and a second PMOS source-follower circuit having a second input stage that is connected to the first reference voltage stage, which is selectively connected to the measurement pad, and a second output stage that is selectively connected to the measurement pad, and
the method further comprises:
repeatedly performing the first level measurement operation to determine a plurality of first ground levels corresponding to a plurality of device temperatures,
measuring, in a first temperature measurement operation, a plurality of levels of the first reference voltage corresponding to the plurality of device temperatures, respectively, through the measurement pad by connecting the second input stage to the measurement pad, without connecting the second output stage and the measurement pad, when the ground voltage stage and the first input stage are connected and the measurement pad and the first output stage are not connected;
measuring, in a second temperature measurement operation, a plurality of first temperature operation levels corresponding to the plurality of device temperatures, respectively, through the measurement pad by connecting the second input stage to the measurement pad and not connecting the second output stage to the measurement pad;
calculating a difference between each of the plurality of levels of the first reference voltage measured in the first temperature measurement operation and each of the plurality of first temperature operation levels measured in the second temperature measurement operation, respectively, and
generating, as a first table generation operation, a first temperature table comprising the plurality of first ground levels measured in the first level measurement operation and the plurality of device temperatures.

4. The method of claim 3, further comprising:
performing the first and second temperature measurement operations and the first table generation operation prior to an execution of the test operation in a temperature incorporation mode; and
performing a first level search operation of determining the first ground level by searching the first temperature table for a current temperature of the semiconductor device,
wherein the first calculation operation comprises calculating a difference between the first ground level determined during the first level search operation and the second ground level measured in the second level measurement operation as the ground variation level.

5. The method of claim 4, wherein when performing the test operation in a temperature non-incorporation mode, the first calculation operation comprises calculating a difference between the first ground level measured during the first level measurement operation and the second ground level measured during the second level measurement operation as the ground variation level.

6. The method of claim 1, wherein when the source-follower circuit is a first NMOS source-follower circuit having a third input stage selectively connected to the source voltage stage and having a third output stage selectively connected to the measurement pad,
the first level measurement operation comprises measuring the first power supply level through the measurement pad in a state in which a second target circuit that is connected to the source voltage stage is disabled,
the second level measurement operation comprises measuring the second power supply level through the measurement pad in a state in which the second target circuit is enabled, and
the first calculation operation comprises calculating a difference between the first and second power supply levels as the power supply variation level.

7. The method of claim 6, wherein:
the semiconductor device further comprises a second voltage generation circuit configured to generate a second reference voltage and to supply the second reference voltage to a second reference voltage stage, and a second NMOS source-follower circuit having a fourth input stage that is connected to the second reference voltage stage, which is selectively connected to the measurement pad, and a fourth output stage that is selectively connected to the measurement pad,
the method further comprises:
repeatedly performing the first level measurement operation to determine a plurality of first power supply levels corresponding to a plurality of device temperatures,
measuring, in a third temperature measurement operation, a plurality of levels of the second reference voltage corresponding to the plurality of device temperatures, respectively, through the measurement pad by connecting the fourth input stage to the measurement pad, without connecting the measurement pad and the fourth output stage, when the source voltage stage and the third input stage are connected and the measurement pad and the third output stage are not connected;
measuring, in a fourth temperature measurement operation, a plurality of second temperature operation levels corresponding to the plurality of device temperatures, respectively, through the measurement pad by connecting the fourth output stage to the measurement pad and not connecting the fourth input stage to the measurement pad;
calculating a difference between each of the plurality of levels of the second reference voltage corresponding to the plurality of device temperatures measured in the third temperature measurement operation and each of the plurality of second temperature operation levels measured during the fourth temperature measurement operation, respectively; and
generating, as a second table generation operation, a second temperature table comprising the plurality of first power supply levels corresponding to the plurality of device temperatures.

8. The method of claim 7, further comprising:
performing the third and fourth temperature measurement operations and the second table generation operation prior to an execution of the test operation in a temperature incorporation mode; and
performing a second level search operation of determining the first power supply level by searching the second temperature table for a current temperature of the semiconductor device,
wherein the first calculation operation comprises calculating a difference between the first power supply level determined during the second level search operation and the second power supply level measured in the second level measurement operation as the power supply variation level.

9. The method of claim 8, wherein the first calculation operation comprises calculating a difference between the first power supply level measured during the first level measurement operation and the second power supply level measured during the second level measurement operation as the power supply variation level when performing the test operation in a temperature non-incorporation mode.

10. The method of claim 1, further comprising adjusting conditions for a preset internal operation to be performed within the semiconductor device with reference to the ground variation level or the power supply variation level after a start of a normal operation that is performed after the test operation.

11. A test system comprising:
a semiconductor device comprising
a target circuit connected to a ground voltage stage or a source voltage stage and configured to perform a preset operation in an enable state, and
a source-follower circuit having an input stage selectively connected to the ground voltage stage or the source voltage stage and an output stage selectively connected to a measurement pad; and
a test device configured
to perform a first level measurement operation of measuring a first ground level or a first power supply level through the measurement pad by connecting the ground voltage stage or the source voltage stage and the measurement pad to the input stage and output stage of the source-follower circuit, respectively, in a state in which the target circuit has been disabled,
to perform a second level measurement operation of measuring a second ground level or a second power supply level through the measurement pad by connecting the ground voltage stage or the source voltage stage and the measurement pad to the input stage and output stage of the source-follower circuit, respectively, in a state in which the target circuit has been enabled, and
to perform a first calculation operation of calculating a difference between the first ground level and the second ground level as a ground variation level or calculating a difference between the first power supply level and the second power supply level as a power supply variation level when performing a test operation on the semiconductor device.

12. The test system of claim 11, wherein the source-follower circuit is a first PMOS source-follower circuit having a first input stage selectively connected to the ground voltage stage and having a first output stage selectively connected to the measurement pad when performing the test operation on the semiconductor device,
wherein the test device is further configured to perform
the first level measurement operation of measuring the first ground level through the measurement pad by connecting the ground voltage stage and the measurement pad to the first input stage and the first output stage, respectively, in a state in which a first target circuit that is connected to the ground voltage stage has been disabled,
the second level measurement operation of measuring the second ground level through the measurement pad by connecting the ground voltage stage and the measurement pad to the first input stage and the first output stage, respectively, in a state in which the first target circuit has been enabled, and
the first calculation operation of calculating the difference between the first and second ground levels as the ground variation level.

13. The test system of claim 12, wherein:
the semiconductor device further comprises a first voltage generation circuit configured to generate a first reference voltage and configured to supply the first reference voltage to a first reference voltage stage, and a second PMOS source-follower circuit having a second input stage that is connected to the first reference voltage stage selectively connected to the measurement pad and having a second output stage selectively connected to the measurement pad, and
the test device is further configured to perform
a plurality of first level measurement operations to determine a plurality of first ground levels corresponding to a plurality of device temperatures,
first temperature measurement operations to measure a plurality of levels of the first reference voltage corresponding to the plurality of device temperatures, respectively, through the measurement pad by connecting the second input stage to the measurement pad, when the ground voltage stage and the first input stage are connected and the measurement pad and the first output stage are not connected,
second temperature measurement operations to measure a plurality of first temperature operation levels corresponding to the plurality of device temperatures, respectively, through the measurement pad by connecting the second input stage to the measurement pad and not connecting the second output stage to the measurement pad, and
a first table generation operation of generating a first temperature table comprising the plurality of first ground levels corresponding to the plurality of device temperatures, respectively, by calculating a difference between each of the plurality of levels of the first reference voltage corresponding to the plurality of device temperatures measured in the first temperature measurement operations and each of the plurality of first temperature operation levels measured during the second temperature measurement operations.

14. The test system of claim 13, wherein the test device is further configured to
generate the first temperature table by performing the first and second temperature measurement operations and the first table generation operation prior to an execution of the test operation on the semiconductor device in a temperature incorporation mode, and
perform a first level search operation of determining the first ground level by searching the first temperature table for a current temperature of the semiconductor device and perform the first calculation operation of calculating a difference between the first ground level determined during the first level search operation and the second ground level measured during the second level measurement operation as the ground variation level.

15. The test system of claim 14, wherein the test device is configured to perform the first calculation operation of calculating a difference between the first ground level measured during the first level measurement operation and the second ground level measured during the second level measurement operation as the ground variation level when performing the test operation in a temperature non-incorporation mode.

16. The test system of claim 11, wherein when the source-follower circuit is a first NMOS source-follower circuit having a third input stage selectively connected to the source voltage stage and having a third output stage selectively connected to the measurement pad,
when performing the test operation on the semiconductor device, the test device is configured to perform
the first level measurement operation of measuring the first power supply level through the measurement pad in a state in which a second target circuit that is connected to the source voltage stage is disabled,
the second level measurement operation of measuring the second power supply level through the measurement pad in a state in which the second target circuit is enabled, and
the first calculation operation of calculating a difference between the first and second power supply levels as the power supply variation level.

17. The test system of claim 16, wherein:
the semiconductor device further comprises a second voltage generation circuit configured to generate a second reference voltage and to supply the second reference voltage to a second reference voltage stage, and a second NMOS source-follower circuit having a fourth input stage that is connected to the second reference voltage stage, which is selectively connected to the measurement pad, and a fourth output stage selectively connected to the measurement pad, and
the test device is further configured to perform
a plurality of third temperature measurement operations to measure a plurality of levels of the second reference voltage corresponding to a plurality of device temperatures, respectively, through the measurement pad by connecting the fourth input stage to the measurement pad in a state in which the source voltage stage and the third input stage are connected and the measurement pad and the third output stage are not connected,
a plurality of fourth temperature measurement operations to measure a plurality of second temperature operation levels corresponding to the plurality of device temperatures, respectively, through the measurement pad by connecting the fourth output stage to the measurement pad, and
a second table generation operation to generate a second temperature table comprising a plurality of first power supply levels corresponding to the plurality of device temperatures, respectively, by calculating a difference between each of the plurality of levels of the second reference voltage and each of the plurality of second temperature operation levels.

18. The test system of claim 17, wherein the test device is further configured to
generate the second temperature table by performing first and second temperature measurement operations and the second table generation operation prior to an execution of the test operation on the semiconductor device in a temperature incorporation mode, and
perform a second level search operation of determining the first power supply level by searching the second temperature table for a current temperature of the semiconductor device and calculate a difference between the first power supply level determined during the second level search operation and the second power supply level measured during the second level measurement operation as the power supply variation level.

19. The test system of claim 18, wherein the test device is configured to perform the first calculation operation of calculating a difference between the first power supply level measured during the first level measurement operation and the second power supply level measured during the second level measurement operation as the power supply variation level when performing the test operation in a temperature non-incorporation mode.

20. The test system of claim 11, wherein the semiconductor device is configured to adjust conditions for a preset internal operation to be performed within the semiconductor device with reference to the ground variation level or the power supply variation level after a start of a normal operation that is performed after the test operation.
